(19) United States
(12) Patent Application Publication
(10) Pub. No.: US 2025/0133853 A1
(43) Pub. Date: Apr. 24, 2025

(54) IMAGE SENSOR

(71) Applicant: Samsung Electronics Co., Ltd., Suwon-si (KR)

(72) Inventors: Jongwoo HONG, Suwon-si (KR); Seokjin KWON, Suwon-si (KR); Beomsuk LEE, Suwon-si (KR); In Sung JOE, Suwon-si (KR); Inyong PARK, Suwon-si (KR); Yangjae YUN, Suwon-si (KR); Sungeun LEE, Suwon-si (KR)

(73) Assignee: Samsung Electronics Co., Ltd., Suwon-si (KR)

(21) Appl. No.: 18/755,040

(22) Filed: Jun. 26, 2024

(30) Foreign Application Priority Data
Oct. 23, 2023 (KR) 10-2023-0142425

(51) Int. Cl. H01L 27/146; G02B 3/02

(52) U.S. Cl. CPC H10F 39/8063; G02B 3/02; H10F 39/024; H10F 39/182; H10F 39/805; H10F 39/8053; G02B 2207/101

(57) ABSTRACT

Disclosed is an image sensor which includes a pixel array including a plurality of unit pixels having photoelectric conversion elements arranged in a matrix form on a semiconductor substrate in a first direction and a second direction crossing the first direction, color filters corresponding to the unit pixels and having at least two different colors, and meta-microlenses on the color filters and configured to condense light incident to the unit pixels.

### CROSS-REFERENCE TO RELATED APPLICATIONS

This application claims priority under 35 U.S.C. § 119 to Korean Patent Application No. 10-2023-0142425 filed on Oct. 23, 2023, in the Korean Intellectual Property Office, the disclosures of which are incorporated by reference herein in their entireties.

### BACKGROUND

Embodiments of the present disclosure described herein relate to image sensors.

An image sensor is a semiconductor-based sensor employed in an optical sensor or an imaging module to convert an optical image into an electrical signal. The image sensor includes a pixel array having a plurality of pixels.

As the optical sensor or the imaging module is made compact, the chief ray angle (CRA) at the edge of the optical sensor is increased. When the chief ray angle at the edge of the optical sensor is increased, the sensitivity of pixels located at the edge of the optical sensor is decreased. This causes degradation in the sensitivity of the optical sensor or the imaging module.

### SUMMARY

Embodiments of the present disclosure provide image sensors with improved sensitivity depending on conditions of incident light.

Embodiments of the present disclosure provide image sensors with improved auto focusing performance by improving light receiving efficiency depending on conditions of incident light.

According to some example embodiments, an image sensor includes a pixel array including a plurality of unit pixels having photoelectric conversion elements arranged in a matrix form on a semiconductor substrate in a first direction and a second direction crossing the first direction, color filters corresponding to the unit pixels and having at least two different colors, and meta-microlenses on the color filters and configured to condense light incident to the unit pixels. Each of the meta-microlenses includes first and second nanostructures having different refractive indexes. The first nanostructure is implemented with a plurality of nanoposts, and diameters of the nanoposts at an edge of the pixel array are greater than diameters of the nanoposts at a center of the pixel array.

In some example embodiments of the present disclosure, the diameters of the nanoposts may be sequentially increased from the center of the pixel array toward the edge of the pixel array.

In some example embodiments of the present disclosure, each of the meta-microlenses includes a refractive index peak region having a highest effective refractive index of a meta-microlens of the meta-microlenses, and a distance between the refractive index peak region and a center of a unit pixel corresponding to the meta-microlens may have different values at the center of the pixel array and the edge of the pixel array.

In some example embodiments of the present disclosure, at least some of the nanoposts may have different diameters in the corresponding unit pixel, and the nanoposts may have the greatest diameter in the refractive index peak region.

In some example embodiments of the present disclosure, the refractive index peak region may be sequentially far away from the center of the corresponding unit pixel with an approach to the edge of the pixel array from the center of the pixel array.

In some example embodiments of the present disclosure, the refractive index peak region may coincide with the center of the corresponding unit pixel at the center of the pixel array.

In some example embodiments of the present disclosure, the nanoposts in the corresponding unit pixel may have different pitches and/or densities at the center of the pixel array and the edge of the pixel array.

In some example embodiments of the present disclosure, the meta-microlenses may be shifted in a direction toward the center with an approach to the edge of the pixel array from the center of the pixel array.

In some example embodiments of the present disclosure, the color filters may be shifted in a direction toward the center with an approach array to the edge of the pixel array from the center of the pixel.

In some example embodiments of the present disclosure, a distance by which the meta-microlenses are shifted may be greater than a distance by which the color filters are shifted.

In some example embodiments of the present disclosure, the color filters may include two or more types of color filters having different colors, and the color filters having the different colors may be shifted by different distances with an approach to the edge of the pixel array from the center of the pixel array.

In some example embodiments of the present disclosure, the color filters may include a red color filter, a green color filter, and a blue color filter, and the red color filter may be shifted more than the green color filter and the blue color filter.

In some example embodiments of the present disclosure, a region where each of the color filters is provided may at least partially overlap a corresponding unit pixel region, and an overlapping area of the region where the color filter is provided and the corresponding unit pixel region may be decreased from the center toward the edge.

In some example embodiments of the present disclosure, a region where each of the meta-microlenses is provided may at least partially overlap a corresponding unit pixel region, and an overlapping area of the region where the meta-microlens is provided and the corresponding unit pixel region may be decreased from the center toward the edge.

In some example embodiments of the present disclosure, the pixel array may include a plurality of regions arranged in a direction from the center of the pixel array to the edge of the pixel array, and the plurality of regions may have a shape of concentric circles.

In some example embodiments of the present disclosure, the meta-microlenses may have a flat upper surface.

In some example embodiments of the present disclosure, the image sensor may further include at least one of an anti-reflective layer, a nano-prism, a color splitter, a color sorter, or a polarizer provided on the meta-microlenses.

In some example embodiments of the present disclosure, each of the unit pixels may include four pixels in a 2×2 array.

According to some example embodiments, a camera module includes an optical lens assembly that condenses light from an object and forms an optical image, an image sensor that converts the optical image formed by the optical lens assembly into an electrical signal, and an image signal processor that processes the electrical signal output from the image sensor into an image signal. The image sensor includes a pixel array including a plurality of unit pixels having photoelectric conversion elements arranged in a matrix form on a semiconductor substrate in a first direction and a second direction crossing the first direction, color filters corresponding to the unit pixels and having at least two different colors, and meta-microlenses on the color filters and configured to condense light incident to the unit pixels. Each of the meta-microlenses includes first and second nanostructures having different refractive indexes. The first nanostructure is implemented with a plurality of nanoposts, and diameters of the nanoposts at an edge of the pixel array are greater than diameters of the nanoposts at a center of the pixel array.

According to some example embodiments, a method for manufacturing the meta-microlenses of the image sensor described above includes forming a low-refractive index material layer on the color filters, forming a plurality of holes by etching the low-refractive index material layer, filling the plurality of holes with a high-refractive index material, and partially removing upper sides of the holes filled with the high-refractive index material through chemical mechanical polishing.

### BRIEF DESCRIPTION OF THE FIGURES

The above and other objects and features of the present disclosure will become apparent by describing in detail embodiments thereof with reference to the accompanying drawings.

FIG. 1 is a block diagram of an image sensor according to some example embodiments of the present disclosure.

FIG. 2 is a plan view illustrating a pixel array according to some example embodiments of the present disclosure, where FIG. 2 illustrates the pixel array that senses light in three different wavelength bands.

FIG. 3 illustrates a camera module in which the image sensor is employed according to some example embodiments of the present disclosure.

FIG. 4 is a plan view for explaining chief ray angles of incident light depending on the positions of a plurality of pixels.

FIGS. 5A and 5B are views for explaining the image sensor having a meta-microlens array employed therein according to some example embodiments of the present disclosure.

FIG. 6 is a view illustrating a meta-microlens according to some example embodiments of the present disclosure.

FIGS. 7A and 7B are sectional views illustrating some of the pixels at the center and edge of an image sensor having a spherical microlens.

FIGS. 8A and 8B are sectional views illustrating some of the pixels at the center and edge of the image sensor according to some example embodiments of the present disclosure.

FIG. 9 is a view illustrating pixel regions in an image sensor according to some example embodiments of the present disclosure.

FIGS. 10A to 10D are plan views sequentially illustrating the shapes of meta-microlenses depending on the positions of the pixel regions.

FIG. 11 is a graph depicting the amounts of light sensed by the image sensor employing the spherical microlens and the image sensor employing the meta-microlens according to some example embodiments of the present disclosure.

FIGS. 12A and 12B are graphs depicting angular response results in the image sensor employing the spherical microlens and the image sensor employing the meta-microlens of the present disclosure.

FIGS. 13A and 13B are simulation result views illustrating light condensing results in the image sensor employing the spherical microlens and the image sensor employing the meta-microlens of the present disclosure.

FIGS. 14A and 14B are sectional views illustrating some of the pixels at the center and edge of the image sensor according to some example embodiments of the present disclosure.

FIGS. 15A to 15D are plan views sequentially illustrating the shapes of the meta-microlenses depending on positions in the pixel array illustrated in FIG. 9.

FIG. 16 is a sectional view illustrating that in the image sensor according to some example embodiments of the present disclosure, not only the meta-microlenses but also the color filters are shifted toward the center of the pixel array and the color filters are shifted to different degrees depending on colors.

FIG. 17 is a plan view at a point corresponding to P4 in FIG. 9.

FIG. 18 is a graph depicting a shift value of each color filter depending on the incidence angle of a chief ray.

FIGS. 19A and 19B are graphs depicting angular response results in the image sensor employing the spherical microlens and the image sensor employing the meta-microlens of the present disclosure.

FIGS. 20A and 20B are graphs depicting angular response results in the image sensor employing the spherical microlens and the image sensor employing the meta-microlens of the present disclosure.

### DETAILED DESCRIPTION

Various changes can be made to the present disclosure, and various embodiments of the present disclosure may be implemented. Thus, specific example embodiments are illustrated in the drawings and described as examples herein. However, it should be understood that the present disclosure is not to be construed as being limited thereto and covers all modifications, equivalents, and alternatives falling within the spirit and scope of the present disclosure.

The present disclosure relates to image sensors. The image sensors are devices that generate a digital signal (or, an electrical signal) based on light reflected from a subject and generates digital image data based on the electrical signal.

Hereinafter, example embodiments of the present disclosure will be described in more detail with reference to the accompanying drawings.

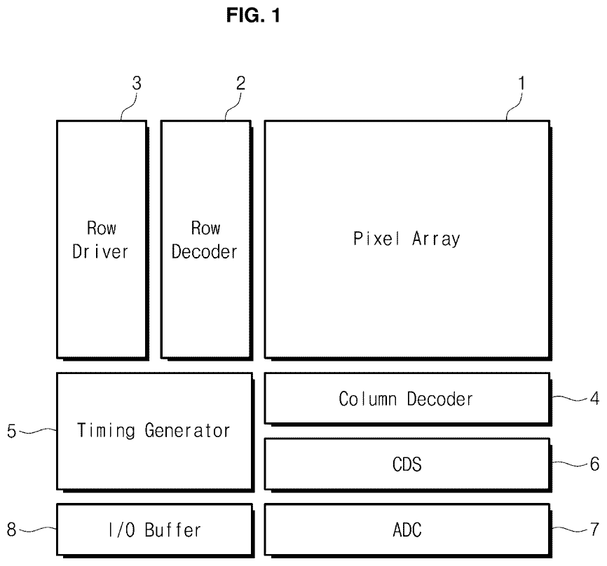

FIG. 1 is a block diagram of an image sensor according to some example embodiments of the present disclosure.

Referring to FIG. 1, the image sensor according to some example embodiments of the present disclosure includes a pixel array 1, a row decoder 2, a row driver 3, a column decoder 4, a timing generator 5, a correlated double sampler (CDS) 6, an analog-to-digital converter (ADC) 7, and an input/output (I/O) buffer 8.

The pixel array 1 includes a plurality of pixels arranged in two dimensions and converts an optical signal into an electrical signal. The pixel array 1 may be driven by a plurality of drive signals such as a pixel selection signal, a reset signal, and a charge transmission signal from the row driver 3. In addition, the converted electrical signal is provided to the correlated double sampler 6.

The row driver 3 provides the plurality of drive signals for driving the plurality of pixels to the pixel array 1 depending on results decoded by the row decoder 2. In a case in which the pixels are arranged in a matrix form, the drive signals may be provided for respective rows.

The timing generator 5 provides a timing signal and a control signal to the row decoder 2 and the column decoder 4.

The correlated double sampler 6 receives, holds, and samples the electrical signal generated by the pixel array 1. The correlated double sampler 6 doubly samples a specific noise level and a signal level by the electrical signal and outputs a difference level corresponding to the difference between the noise level and the signal level.

The analog-to-digital converter 7 converts an analog signal corresponding to the difference level output from the correlated double sampler 6 into a digital signal and outputs the digital signal.

The input/output buffer 8 latches the digital signal. The input/output buffer 8 outputs the latched signal to an image signal processor (not illustrated) as a digital signal depending on a result decoded by the column decoder 4.

The pixel array 1 may include the plurality of pixels that sense light in different wavelength bands. The arrangement of the plurality of pixels may be implemented in various ways.

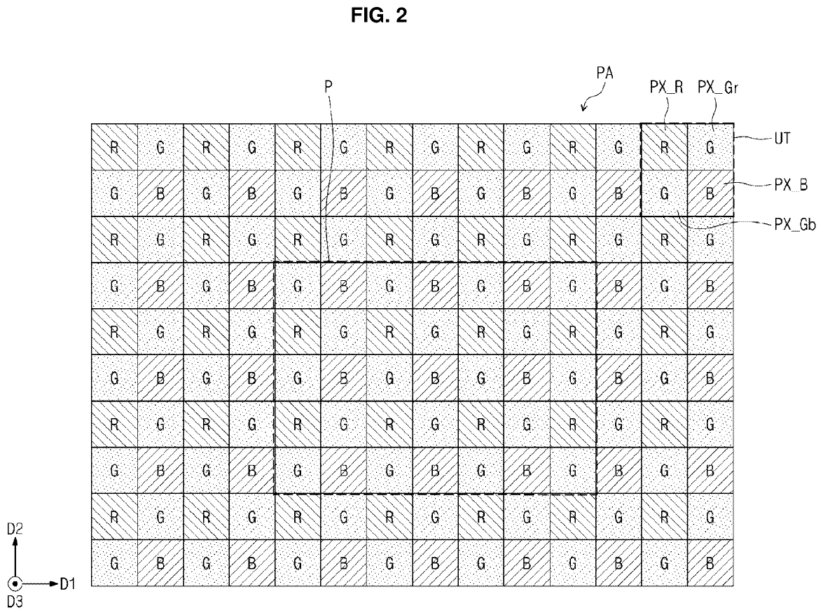

FIG. 2 is a plan view illustrating the pixel array according to some example embodiments of the present disclosure, where FIG. 2 illustrates the pixel array that senses light in three different wavelength bands.

Referring to FIG. 2, the pixel array includes red unit pixels PX_R, green unit pixels PX_Gr and PX_Gb, and blue unit pixels PX_B that are arranged in a matrix form and that represent certain colors, for example, colors corresponding to red (R), green (G), and blue (B).

In some example embodiments of the present disclosure, the red unit pixels PX_R, the green unit pixels PX_Gr and PX_Gb, and the blue unit pixels PX_B may be arranged in a certain arrangement order to constitute a Bayer pattern commonly employed in image sensors. The Bayer pattern includes a plurality of unit patterns UT. One unit pattern UT includes four quadrant regions. The unit pattern UT is repeatedly arranged in two dimensions in a first direction D1 and a second direction D2. In other words, within a unit pattern in the form of a 2×2 array, one red unit pixel PX_R and one blue unit pixel PX_B are arranged in one diagonal direction, and two green unit pixels PX_Gr and PX_Gb are arranged in the other diagonal direction. When the overall pixel arrangement is viewed, a first row in which a plurality of red unit pixels PX_R and a plurality of green unit pixels PX_Gr are alternately arranged in the first direction D1 and a second row in which a plurality of green unit pixels PX_Gb and a plurality of blue unit pixels PX_B are alternately arranged in the first direction D1 are repeatedly arranged in the second direction D2. For reference, in the drawing, a direction perpendicular to the first direction D1 and the second direction D2 is a third direction D3.

The image sensor may be applied to various optical devices, for example, a camera module.

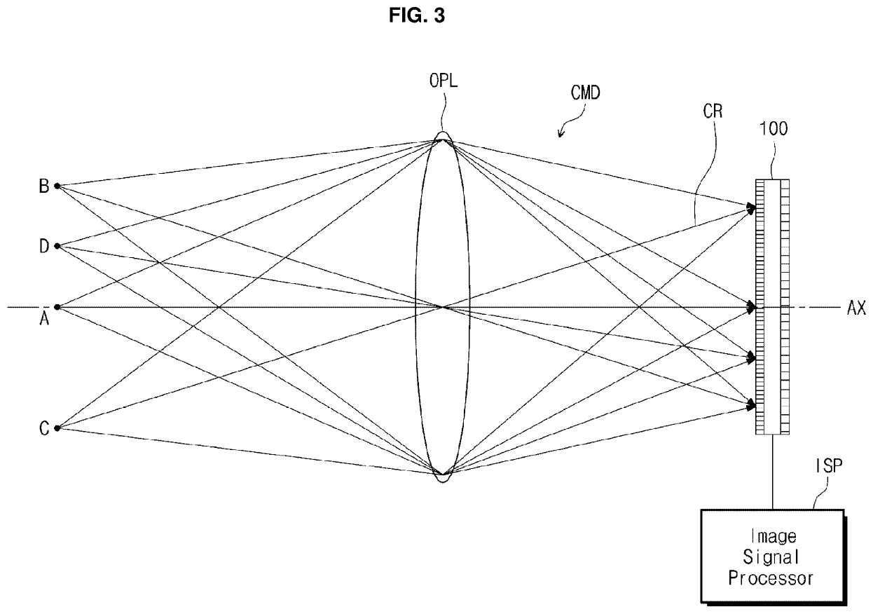

FIG. 3 illustrates the camera module in which the image sensor is employed according to some example embodiments of the present disclosure.

Referring to FIG. 3, the camera module CMD according to some example embodiments may include an optical lens assembly OPL that condenses light reflected from an object and forms an optical image, the image sensor 100 that converts the optical image formed by the optical lens assembly OPL into an electrical signal, and an image signal processor ISP that processes the electrical signal output from the image sensor 100 into an image signal. The camera module CMD may further include an IR cut filter disposed between the image sensor 100 and the optical lens assembly OPL, a display panel that displays an image formed by the image signal processor ISP, and a memory that stores image data formed by the image signal processor ISP. The camera module CMD may be mounted in, for example, a mobile electronic device such as a mobile phone, a notebook computer, or a tablet PC.

The optical lens assembly OPL serves to focus an image of a subject outside the camera module CMD on the image sensor 100, more accurately, the pixel array of the image sensor 100. Although briefly illustrated as one lens in FIG. 3 for convenience, the actual optical lens assembly OPL may include a plurality of lenses. When the pixel array is accurately located on the focal plane of the optical lens assembly OPL, light starting from a point on the subject passes through the optical lens assembly OPL and converges to a point on the pixel array again. For example, light starting from a point A on an optical axis AX passes through the optical lens assembly OPL and thereafter converges to the center of the pixel array located on the optical axis AX. Light starting from a point B, C, or D off the optical axis AX crosses the optical axis AX by the optical lens assembly OPL and thereafter converges to a point on a peripheral portion of the pixel array. For example, in FIG. 3, light starting from the point B above the optical axis AX crosses the optical axis AX and thereafter converges to a point at the lower edge of the pixel array, and light starting from the point C below the optical axis AX crosses the optical axis AX and thereafter converges to a point at the upper edge of the pixel array. In addition, light starting from the point D located between the optical axis AX and the point B crosses the optical axis AX and thereafter converges to a point between the center of the pixel array and the lower edge of the pixel array.

Accordingly, the light starting from the different points A, B, C, and D is incident to the pixel array at different angles depending on the distances between the points A, B, C, and D and the optical axis AX. The incidence angle of light incident to the pixel array is typically defined as the chief ray angle (CRA). A chief ray (CR) refers to a ray incident from a point on the subject to the pixel array through the center of the optical lens assembly OPL, and the chief ray angle refers to the angle formed by the chief ray with the optical axis AX. The light starting from the point A on the optical axis AX has a chief ray angle of 0 degrees and is perpendicularly incident to the pixel array. As the distance between a starting point and the optical axis AX is increased, the chief ray angle is increased.

From the perspective of the image sensor 100, the chief ray angle of light incident to the center of the pixel array is 0 degrees, and the chief ray angle of incident light is increased toward the edge of the pixel array. For example, the light that starts from the points B and C and is incident to the outermost edge of the pixel array has the largest chief ray angle, and the light that starts from the point A and is incident to the center of the pixel array has a chief ray angle of 0 degrees. In addition, the light that starts from the point D and is incident between the center of the pixel array and the edge of the pixel array has a chief ray angle greater than 0 degrees and smaller than the chief ray angles of the light starting from the points B and C.

Accordingly, the chief ray angles of incident light incident to the plurality of pixels vary depending on the positions of the plurality of pixels in the pixel array.

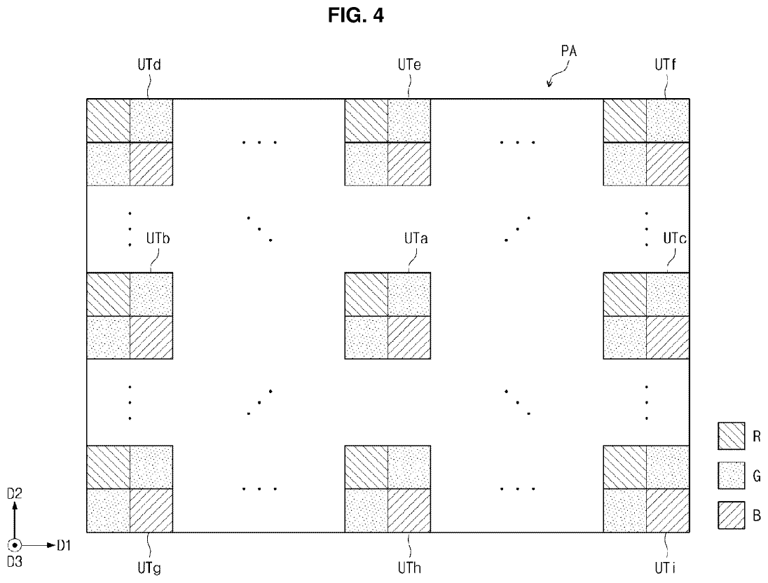

FIG. 4 is a plan view for explaining the chief ray angles of incident light depending on the positions of the plurality of pixels.

Referring to FIG. 4, the chief ray angles in the first direction D1 and the second direction D2 at the center UTa of the pixel array PA are 0 degrees. The chief ray angle in the first direction D1 is gradually increased farther away from the center UTa in the first direction D1. The chief ray angle in the first direction D1 is largest at opposite edges UTb and UTc in the first direction D1. The chief ray angle in the second direction D2 is gradually increased farther away from the center UTa in the second direction D2. The chief ray angle in the second direction D2 is largest at opposite edges UTe and UTh in the second direction D2. Both the chief ray angle in the first direction D1 and the chief ray angle in the second direction D2 are gradually increased farther away from the center UTa in diagonal directions. The chief ray angles in the first and second directions D1 and D2 are largest at vertexes UTd, UTf, UTg, and UTi. When the chief ray angles of incident light incident to the pixels are increased, the sensitivities of the pixels may be lowered.

In some example embodiments of the present disclosure, to prevent, reduce, or minimize deterioration in the sensitivities of pixels located at the edge of the pixel array PA, a meta-microlens array is disposed in the pixel array PA.

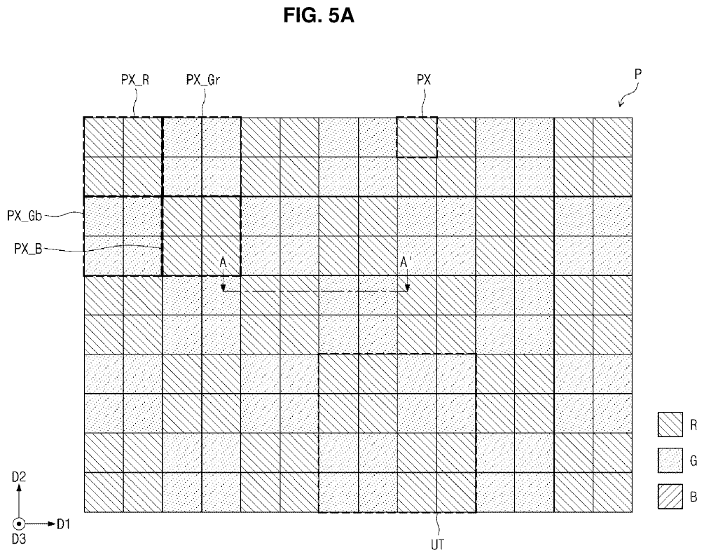

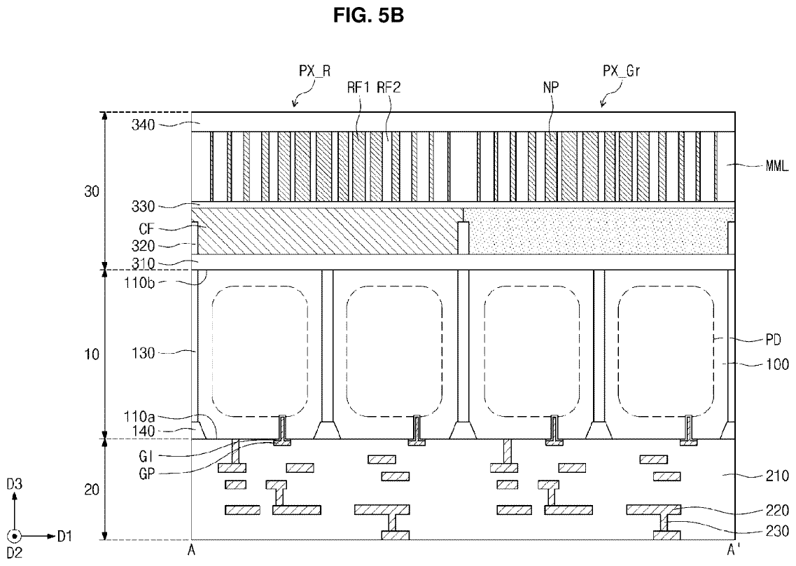

FIGS. 5A and 5B are views for explaining the image sensor according to some example embodiments of the present disclosure. FIG. 5A is a plan view illustrating a portion of the pixel array according to some example embodiments of the present disclosure, where FIG. 5A corresponds to a region P of FIG. 2. FIG. 5B is a sectional view taken along line A-A′ of FIG. 5A.

Referring to FIGS. 5A and 5B, when viewed from above the plane, the pixel array includes the plurality of unit patterns UT arranged in a matrix form along the Bayer pattern. Each of the plurality of unit patterns UT may include unit pixels representing respective colors, that is, the red unit pixel PX_R, the green unit pixel PX_Gr, the green unit pixel PX_Gb, and the blue unit pixel PX_B.

Each of the unit pixels representing the respective colors may include a plurality of pixels, for example, four pixels PX. According to these example embodiments, the four pixels PX may be arranged in a matrix form in the first direction D1 and the second direction D2 crossing each other.

In some example embodiments of the present disclosure, pixels PX constituting one unit pixel correspond to one color and share one meta-microlens (MML). For example, as illustrated in FIG. 5B, two pixels PX adjacent to each other in the row direction (that is, the first direction D1) correspond to one red unit pixel PX_R and share one meta-microlens (MML), and two other pixels PX adjacent to each other in the row direction correspond to one green unit pixel PX_Gr and share one meta-microlens. As described above, two pixels PX adjacent to each other may share one meta-microlens MML, but may include separate photoelectric conversion regions PD, respectively. Accordingly, separate incident light may enter the two pixels PX adjacent to each other in the row direction, and the phase difference of the light provided to the two pixels PX on the left and right sides may be obtained. Thus, auto focusing of the image sensor is possible by measuring the phase difference of the light incident to the one unit pixel. Each pixel PX may obtain an image signal when not used for auto focusing. In this case, a method of collecting information from two pixels PX adjacent to each other may be used.

In some example embodiments of the present disclosure, for convenience of description, it has been described that one unit pixel includes four pixels. However, the present disclosure is not limited thereto, and in some example embodiments of the present disclosure, one unit pixel may include, for example, nine or sixteen pixels.

When the image sensor according to some example embodiments of the present disclosure is viewed in the sectional view, the image sensor may include a photoelectric conversion layer 10, a circuit wiring layer 20, and a light transmitting layer 30. The photoelectric conversion layer 10 may be disposed between the circuit wiring layer 20 and the light transmitting layer 30.

The photoelectric conversion layer 10 includes a semiconductor substrate 110 having a first surface 110a and a second surface 110b facing away from each other, device isolation films 130 penetrating the semiconductor substrate 110, and the photoelectric conversion regions PD provided in the semiconductor substrate 110. (Here, the photoelectric conversion regions are regions corresponding to photoelectric conversion elements and are assigned with the same reference numeral PD as that of the photoelectric conversion elements.)

The semiconductor substrate 110 is a region where the pixel array having the plurality of pixels PX arranged therein is provided. The semiconductor substrate 110 may be a silicon substrate, a germanium substrate, a silicon-germanium substrate, a Group II-VI compound semiconductor substrate, a Group III-V compound semiconductor substrate, or a silicon on insulator (SOI) substrate. The semiconductor substrate 110 may include a first conductive type impurity. Accordingly, the semiconductor substrate 110 may have a first conductive type. The first conductive type impurity may be a Group III element. For example, the first conductive type impurity may include a P-type impurity such as aluminum (Al), boron (B), indium (in), and/or gallium (Ga).

The plurality of pixels PX may be arranged in a matrix form in the semiconductor substrate 110 in the first direction D1 and the second direction D2 parallel to the first surface 110a of the semiconductor substrate 110. The first direction D1 and the second direction D2 may cross each other. For example, the first direction D1 and the second direction D2 may be perpendicular to each other.

The device isolation films 130 penetrate the semiconductor substrate 110 and are disposed between the pixels PX. The pixels PX may be defined by the device isolation films 130. The device isolation films 130 may penetrate the semiconductor substrate 110 in the third direction D3 perpendicular to the first surface 110a. That is, the device isolation films 130 may extend from the first surface 110a toward the second surface 110b. The first surface 110a may expose the lower surfaces of the device isolation films 130 and may be substantially coplanar or coplanar with the lower surfaces of the device isolation films 130. The second surface 110b may expose the upper surfaces of the device isolation films 130 and may be substantially coplanar or coplanar with the upper surfaces of the device isolation films 130.

The photoelectric conversion regions PD may be disposed in the pixels PX, respectively. The photoelectric conversion elements PD may be disposed in the semiconductor substrate 110. The photoelectric conversion elements PD may absorb incident light and may generate and accumulate charges corresponding to the amount of light. The photoelectric conversion elements PD may include at least one of a photoelectric conversion element, a photo transistor, a photo gate, a pinned photo diode (PPD), or a combination thereof. The photoelectric conversion regions PD may be disposed behind the meta-microlenses MML and color filters CF and may correspond to, for example, photo diodes. When light reaches the photoelectric conversion regions PD, the photoelectric conversion regions PD may output electrical signals corresponding to the incident light through a photoelectric effect. The electrical signals may generate charges (or, currents) depending on the intensity (or, amount) of the received light.

The photoelectric conversion regions PD may be interposed between the first surface 110a and the second surface 110b of the semiconductor substrate 110. The photoelectric conversion regions PD may be doped regions including a second conductive type impurity opposite to the first conductive type impurity. In some example embodiments of the present disclosure, the photoelectric conversion regions PD may include a Group V element as an impurity, and the Group V element may be the second conductive type impurity. The second conductive type impurity may include an n-type impurity such as phosphorus (P), arsenic (As), bismuth (Bi), and/or antimony (Sb). The photoelectric conversion regions PD may form a PN junction with the semiconductor substrate 110 to form photo diodes.

Shallow separation films 140 may be provided in the respective pixels PX. The shallow separation films 140 may be buried the semiconductor substrate 110 and may be disposed adjacent to the first surface 110a. Pad films 141 may be provided between the shallow separation films 140 and the semiconductor substrate 110. The upper surfaces of the shallow separation films 140 may be exposed by the first surface 110a. The shallow separation films 140 may be formed of various insulating materials. For example, the shallow separation films 140 may include at least one of a silicon oxide film, a silicon nitride film, or a silicon oxy nitride film.

The circuit wiring layer 20 may be provided on the first surface 110a of the semiconductor substrate 110. The circuit wiring layer 20 may include a circuit part, contact VIAs 230, and conductive lines 220. The circuit part may include gate patterns GP and gate insulating layers GI, and the contact VIAs 230 and the conductive lines 220 may be connected with the circuit part. The contact VIAs 230 and the conductive lines 220 may be provided in an interlayer insulating layer 210 stacked on the first surface 110a. The interlayer insulating layer 210 may cover the first surface 110a, the upper surfaces of the device isolation films 130, and the upper surfaces of the shallow separation films 140. The interlayer insulating layer 210 may cover transistors constituting the circuit part. The conductive lines 220 may be electrically connected to the transistors through the contact VIAs 230. The interlayer insulating layer 210 may include an insulating material, and the contact VIAs 230 and the conductive lines 220 may include a conductive material.

The gate patterns GP may be disposed on the first surface 110a of the semiconductor substrate 110. The gate patterns GP may function as gate electrodes of transfer transistors, source follower transistors, reset transistors, or selection transistors for driving the image sensor. For example, the gate patterns GP may include transfer gates, source follower gates, reset gates, or selection gates. In the drawing, for convenience of description, one gate pattern GP is illustrated as being disposed in each pixel PX. However, without being limited thereto, a plurality of gate patterns GP may be disposed in each pixel PX. As illustrated, the gate patterns GP may have a buried gate structure. However, without being limited thereto, the gate patterns GP may have a planar gate structure unlike that illustrated in the drawing. The gate patterns GP may include a metallic material, a metal silicide material, poly silicon, or a combination thereof.

The gate insulating layers GI may be interposed between the gate patterns GP and the semiconductor substrate 110. The gate insulating layers GI may include, for example, a silicon-based insulating material (e.g., silicon oxide, silicon nitride, and/or silicon oxy nitride) and/or a high-k material (e.g., hafnium oxide and/or aluminum oxide).

The light transmitting layer 30 may be disposed on the second surface 110b of the semiconductor substrate 110. The light transmitting layer 30 is a layer through which light travelling from the outside toward the photoelectric conversion regions PD transmits, and the second surface 110b of the semiconductor substrate 110 is a light incident surface to which light is incident. The light transmitting layer 30 may condense and filter light incident from the outside and may provide the light to the photoelectric conversion layer 10. The light transmitting layer 30 may include the color filters CF, fence patterns 320, and the meta-microlenses MML that are disposed on the second surface 110b.

The color filters CF may be disposed between the second surface 110b and the meta-microlenses MML. The color filters CF may include at least two types of color filters having different wavelength bands. For example, the color filters CF may be allocated to the red unit pixel PX_R, the green unit pixels PX_Gr and PX_Gb, and the blue unit pixel PX_B to implement red, green, and blue, respectively. Red, green, and blue (RGB), red, green, blue, and white (RGBW), cyan, magenta, and yellow (CMY), cyan, magenta, yellow, and black (CMYK), red, yellow, and blue (RYB), and infrared ray (RGBIR) may serve as examples of a plurality of reference colors. Although it has been described that the color filters CF implement red (R), green (G), and blue (B), the present disclosure is not limited thereto. The color filters CF corresponding to the respective pixels PX constitute a color filter array.

Hereinafter, for convenience of description, the description will be focused on the Bayer pattern, that is, the RGB pattern (or the RGGB pattern). However, it should be noted that this does not limit the repetitive arrangement structures and patterns of other color filter arrays. That is, example embodiments of the present disclosure are not limited thereto, and the color filter array may be formed in various patterns including RGB, CYYM, CYGM, RGBW, RYYB, and X-trans.

The fence patterns 320 may be disposed on the device isolation films 130. The fence patterns 320 may vertically overlap the device isolation films 130. The fence patterns 320 may have a planar shape corresponding to the device isolation films 130. For example, the fence patterns 320 may have a grid shape when viewed from above the plane. The fence patterns 320 may surround the color filters CF when viewed from above the plane. The fence patterns 320 may be disposed such that at least portions thereof vertically overlap the device isolation films 130 (e.g., in the third direction D3).

Each of the fence patterns 320 may be interposed between two color filters CF adjacent to each other. The plurality of color filters CF may be physically or optically separated from one another by the fence patterns 320. Accordingly, the fence patterns 320 may guide light incident to the second surface 110b such that the light is input into the photoelectric conversion regions PD.

The fence patterns 320 may include metal. However, without being limited thereto, the fence patterns 320 may include a low-refractive index material. The low-refractive index material may include a polymer and silica nano particles in the polymer. The low-refractive index material may have insulating characteristics. In another example, the fence patterns 320 may include metal and/or metal nitride. For example, the fence patterns 320 may include titanium and/or titanium nitride.

The meta-microlenses MML may be planar microlenses using nanostructures and may be disposed on the plurality of color filters CF. Each of the meta-microlenses MML includes a nanostructure that has a sub-wavelength period and locally adjusts the refractive index of incident light. The nanostructure is an optical element that locally adjusts the refractive index of incident light to control the polarization, phase, and size of the light. When light transmits through the nanostructure having a sub-wavelength or less, the effective refractive index is determined depending on the ratio between the structure and the surrounding material. In some example embodiments of the present disclosure, the phase delay of transmitted light is adjusted by locally adjusting the ratio of materials having different refractive indexes in the portion through which the light transmits.

The meta-microlenses MML may be disposed such that at least portions thereof vertically overlap the photoelectric conversion regions PD (e.g., in the third direction D3). The meta-microlenses MML may be provided at positions corresponding to the photoelectric conversion regions PD of the semiconductor substrate 110.

Although it has been described that the color filters CF, the fence patterns 320, and/or the meta-microlenses MML are provided at the positions corresponding to the respective pixels PX in an overlapping manner, the present disclosure is not limited thereto. At least one of the color filters CF, the fence patterns 320, or the meta-microlenses MML may have an offset structure shifted to a certain degree from the positions corresponding to the respective pixels PX. The offset structure may be intentionally selected to optimize an optical path in consideration of the angle of light traveling from the outside toward the pixels PX. The meta-microlenses MML and the offset structure will be described below.

A passivation layer 340 may be provided on the meta-microlenses MML. The passivation layer 340 may be formed of a single layer or multiple layers. The passivation layer 340 may not only function as a protective layer for protecting the meta-microlenses MML, but may also function as an anti-reflective layer that prevents or reduces light from the outside from being reflected by the upper surfaces of the meta-microlenses MML. The passivation layer 340 may be formed of various materials. For example, the passivation layer 340 may include hafnium oxide (HfOx), silicon oxide (SiOx), zirconium oxide (ZrO₂), titanium oxide (TiO₂), or aluminum oxide (Al₂O₃, alumina). In this case, the passivation layer 340 may prevent or reduce reflection of light such that light travelling toward the second surface 110b through the meta-microlenses MML effectively reaches the photoelectric conversion regions PD.

An upper insulating layer 310 may be interposed between the second surface 110b of the semiconductor substrate 110 and the color filters CF and between the device isolation films 130 and the fence patterns 320. The upper insulating layer 310 may cover the second surface 110b of the semiconductor substrate 110 and the upper surfaces of the device isolation films 130. The upper insulating layer 310 may include a plurality of layers. For example, the upper insulating layer 310 may include an anti-reflective layer. The anti-reflective layer may be formed of various materials. For example, the anti-reflective layer may include hafnium oxide (HfOx), silicon oxide (SiOx), zirconium oxide (ZrO₂), titanium oxide (TiO₂), or aluminum oxide (Al₂O₃, alumina). In this case, the upper insulating layer 310 may prevent or reduce reflection of light such that light incident to the second surface 110b of the semiconductor substrate 110 effectively reaches the photoelectric conversion regions PD.

An etch-preventing insulation layer 330 may be provided between the color filters CF and the meta-microlenses MML. The etch-preventing insulation layer 330 may be an insulation layer for preventing or reducing over-etching when the meta-microlenses MML are formed using an etching process. Although not illustrated, a capping insulating layer for covering the upper surfaces of the color filters CF and/or a spacer layer for securing a gap between the color filters CF and the meta-microlenses MML may be additionally provided between the color filters CF and the etch-preventing insulation layer 330.

The meta-microlenses MML serve to refract and/or condense light.

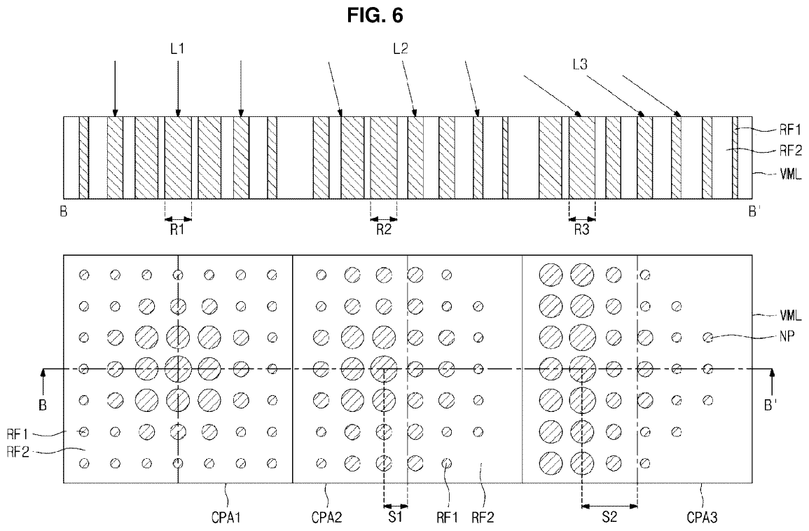

FIG. 6 is a view illustrating the meta-microlens MML according to some example embodiments of the present disclosure. FIG. 6 illustrates a plan view of the meta-microlens MML and a sectional view taken along line B-B′ in the plan view of the meta-microlens MML.

Referring to FIG. 6, the meta-microlens MML may include high-refractive index nanostructures RF1 and a low-refractive index nanostructure RF2 filled between the high-refractive index nanostructures RF1. The high-refractive index nanostructures RF1 may be formed of a dielectric material, such as TiO₂, GaN, ZnS, ZnSe, or SiNx (e.g., Si₃N₄), which has a relatively high refractive index and a low absorption rate in the visible wavelength band. The low-refractive index nanostructure RF2 may be formed of a dielectric material, such as SiO₂, siloxane-based spin on glass (SOG), or air, which has a relatively low refractive index and a low absorption rate in the visible wavelength band.

The meta-microlens MML may include a plurality of nanoposts NP as the high-refractive index nanostructures RF1. In some example embodiments of the present disclosure, when viewed based on one unit pixel region, the plurality of high-refractive index nanostructures RF1 may be disposed in the form of the nanoposts NP on the plane, and the low-refractive index nanostructure RF2 may fill the remaining regions other than the nanoposts NP.

The nanoposts NP according to some example embodiments of the present disclosure may have a cylindrical shape. In FIG. 6, it is exemplified that the plurality of high-refractive index nanostructures RF1 have a cylindrical shape. However, the cross-sections of the plurality of high-refractive index nanostructures RF1 may have, for example, an oval or polygonal shape (or other shapes) rather than a circular shape.

The effective refractive index of the meta-microlens MML may be highest in one region of the meta-microlens MML and may be gradually decreased farther away from the one region such that the meta-microlens MML serves as a convex lens that allows light to converge. In other words, the ratio of the high-refractive index nanostructures RF1 to the low-refractive index nanostructure RF2 may be highest in one region of the meta-microlens MML and may gradually decrease farther away from the one region.

Hereinafter, the region where the effective refractive index is highest within the meta-microlens MML is referred to as the “refractive index peak region”. The diameters and pitches of the nanoposts NP may be differently selected in the refractive index peak region and the region around the refractive index peak region such that the effective refractive index appears depending on the regions. That is, the diameters, number, and areas of the nanoposts NP may vary depending on the form of light collection to be achieved. For example, the nanoposts NP may be provided in various ways such that the nanoposts NP have the same diameter or different diameters within a unit pixel. In this case, the nanoposts NP may be disposed such that the nanoposts NP in the refractive index peak region have the greatest diameter.

As described above, the chief ray angle of incident light varies depending on the position on the pixel array. Accordingly, the position of the refractive index peak region within the meta-microlens MML may vary depending on the position of the meta-microlens MML within the pixel array. When the meta-microlens MML is disposed at the center of the pixel array to which light is nearly perpendicularly incident, the meta-microlens MML does not have to change the angle at which the light travels. However, when the meta-microlens MML is disposed at the edge of the pixel array to which light is obliquely incident, the angle at which the light travels needs to be changed by the meta-microlens MML.

To this end, according to some example embodiments of the present disclosure, the diameters and arrangement of the nanoposts NP may vary depending on the incidence angles of chief rays. When three light beams, the incidence angles of which are sequentially increased, are referred to as first light L1, second light L2, and third light L3, respectively, and color pixel regions disposed in three regions where the incidence angles of incident chief rays are different from one another are referred to as first to third color pixel regions CPA1, CPA2, and CPA3, respectively, the diameters and arrangement of the nanoposts NP in the first to third color pixel regions CPA1, CPA2, and CPA3 may be differently set depending on the incidence angles of the first light L1, the second light L2, and the third light L3.

In some example embodiments of the present disclosure, the nanoposts NP provided in each of the color pixel regions CPA1, CPA2, and CPA3 may have the greatest diameter in the refractive index peak region, and the diameters of the nanoposts NP may be decreased farther away from the refractive index peak region. In addition, the refractive index peak region may be shifted from the center of each color pixel region depending on the angle of incident light. For example, in the first color pixel region CPA1 to which the first light L1 is incident at an angle of 0 degrees, the refractive index peak region may coincide with the center of the first color pixel region CPA1. However, in the second color pixel region CPA2 and the third color pixel region CPA3 to which the second light L2 and the third light L3, which are inclined when compared to the first light L1, are incident, the refractive index peak regions may be shifted and spaced apart from the centers of the color pixel regions. In the second color pixel region CPA2 to which the second light L2 is incident, the refractive index peak region may be shifted from the center of the second color pixel region CPA2 by a first distance S1, and in the third color pixel region CPA3 to which the third light L3 is incident, the refractive index peak region may be shifted from the center of the third color pixel region CPA3 by a second distance S2. Here, the refractive index peak region in the third color pixel region CPA3 may be shifted more than the refractive index peak region in the second color pixel region CPA2, and therefore the second distance S2 may be greater than the first distance S1.

In some example embodiments of the present disclosure, the diameters of the nanoposts NP may also be changed depending on the incidence angles of the chief rays. When the diameters of the nanoposts NP in the refractive index peak regions of the first to third color pixel regions CPA1, CPA2, and CPA3 are referred to as first to third diameters R1, R2, and R3, the first to third diameters R1, R2, and R3 may be sequentially increased in the order of the first diameter R1, the second diameter R2, and the third diameter R3.

When light transmits through a certain material, phase modulation occurs due to the refractive index of the material. For example, when light having a certain wavelength transmits through a material having a period smaller than or equal to the certain wavelength, the phase of the transmitted light varies depending on the ratio of constituent materials. Since the meta-microlens MML is formed of two materials having different effective refractive indexes and the diameters of the nanoposts NP having a high refractive index are varied, the phase of light transmitting through the meta-microlens MML is changed.

In general, a method of refracting light using a spherical microlens having a physically protruding shape (hereinafter, referred to as the spherical microlens) is used. In the case of the spherical microlens, an optical path is controlled by changing the height for each position. However, in some example embodiments of the present disclosure, an optical path is controlled by adjusting the diameters of the nanoposts NP depending on the position where light is incident and the resulting incidence angle. That is, a structure that delays a phase is intentionally disposed at each position, and the degree of phase delay is controlled by the diameters of the nanoposts NP. In this case, when the diameters of the nanoposts NP are small, the phase delay is small, and as the diameters of the nanoposts NP are increased, the phase delay is increased. As a result, light may be deflected in one direction. By arranging the nanoposts NP using this principle, light obliquely incident to the upper surface of the meta-microlens MML may be refracted and vertically emitted from the lower surface of the meta-microlens MML. In some example embodiments of the present disclosure, the diameters of the nanoposts NP may be sequentially increased such that the deflection of traveling light increases as the incidence angle increases.

In some example embodiments of the present disclosure, the average diameters of the nanoposts NP provided in the first to third color pixel regions CPA1, CPA2, and CPA3 may be gradually increased as the incidence angle is increased. That is, the average diameter of the nanoposts NP provided in the second color pixel region CPA2 may be greater than the average diameter of the nanoposts NP provided in the first color pixel region CPA1. Furthermore, the average diameter of the nanoposts NP provided in the third color pixel region CPA3 may be greater than the average diameter of the nanoposts NP provided in the second color pixel region CPA2.

In addition, the densities of the nanoposts NP in the refractive index peak regions of the first to third color pixel regions CPA1, CPA2, and CPA3 may be increased in the order of the first color pixel region CPA1, the second color pixel region CPA2, and the third color pixel region CPA3. Although FIG. 6 illustrates an example that the pitches of the nanoposts NP are substantially constant or constant, the present disclosure is not limited thereto, and the pitches of the nanoposts NP may be adjusted in various ways. For example, the pitch of the nanoposts NP in the refractive index peak region may be set to be relatively narrow, and the pitches in the regions other than the refractive index peak region may be set to be relatively wide. In some example embodiments of the present disclosure, the pitches of the nanoposts NP may have a decreasing value from the first color pixel region CPA1 toward the third color pixel region CPA3.

The above-described meta-microlens MML may be manufactured by forming a low-refractive index material layer on the color filter CF, etching the low-refractive index material layer to form a plurality of holes, and filling the holes with a high-refractive index material. Referring to FIGS. 5B and 6, in more detail, the low-refractive index material layer is formed on the semiconductor substrate 110, on which the color filter CF and the fence pattern 320 are formed, through deposition, and the plurality of holes are formed through a photolithography process and an etching process. The etch-preventing insulation layer 330 may be interposed between the low-refractive index material layer and the color filter CF and the fence pattern 320. The etch-preventing insulation layer 330 prevents or reduces the part under the etch-preventing insulation layer 330 from being etched when the low-refractive index material layer is etched.

The plurality of holes are formed to correspond to regions where the nanoposts NP are to be formed. Next, a high-refractive index material layer is formed on the semiconductor substrate 110 through deposition. The high-refractive index material layer fills the plurality of holes. Then, the meta-microlens MML is formed by performing a chemical mechanical polishing (CMP) process on the upper surface of the semiconductor substrate, on which the high-refractive index material layer is formed, until the upper surface of the low-refractive index material layer is exposed. This process may be performed several times to increase the heights of the nanoposts NP. The passivation layer 340 may be provided on the manufactured meta-microlens MML. The passivation layer 340 may be formed of a single layer or multiple layers. The passivation layer 340 may not only function as a protective layer for protecting the meta-microlenses MML, but may also function as an anti-reflective layer that prevents or reduces light from the outside from being reflected by the upper surfaces of the meta-microlenses MML.

In some example embodiments of the present disclosure, unlike a commonly used spherical microlens, the meta-microlens MML has a flat upper surface shape. Accordingly, various additional functional layers may be stacked on the meta-microlens MML. Although not illustrated, for example, an infrared filter layer may be stacked on the meta-microlens MML, and in this case, flare may be prevented or reduced. Alternatively, various nanostructure layers, such as a nano-prism, a color splitter, a color sorter, and/or a polarizer, may be additionally formed on the meta-microlens MML.

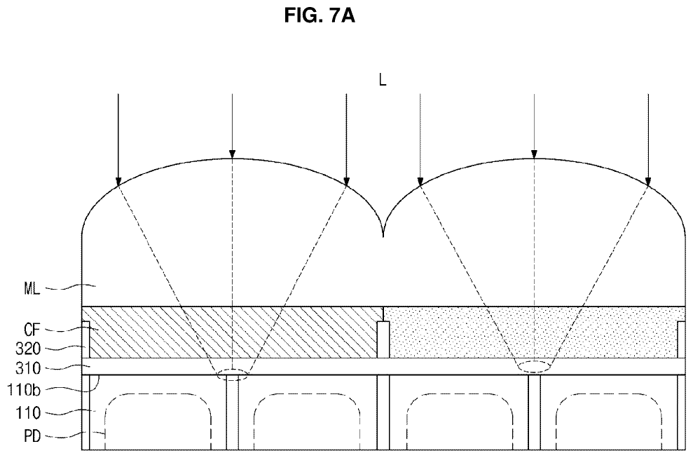

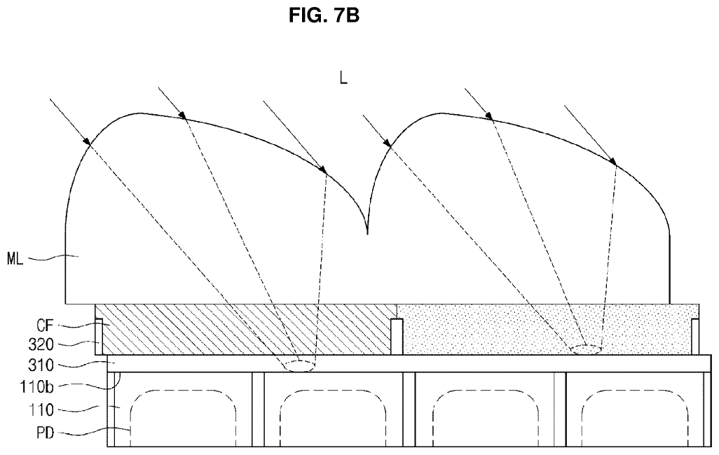

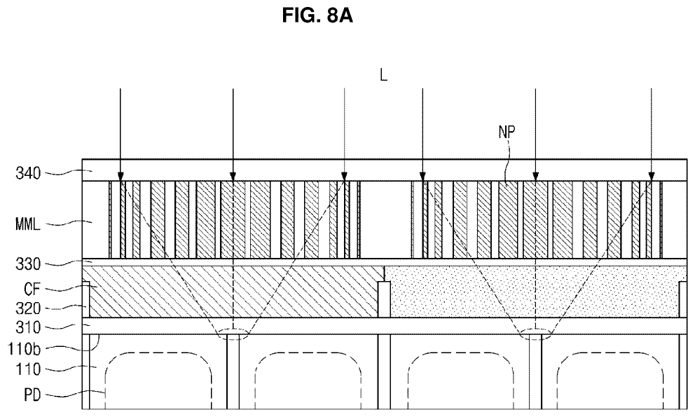

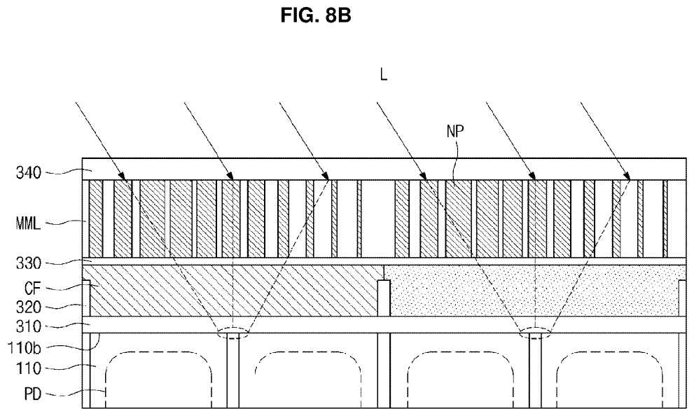

FIGS. 7A, 7B, 8A, and 8B are views for explaining optical paths of image sensors having different microlenses. FIGS. 7A and 7B are sectional views illustrating some of the pixels at the center and edge of an image sensor having a spherical microlens. FIGS. 8A and 8B are sectional views illustrating some of the pixels at the center and edge of the image sensor according to some example embodiments of the present disclosure.

Referring to FIGS. 7A and 7B, in the image sensor including the spherical microlenses ML, the highest point of a spherical microlens ML corresponding to the center of a pixel array corresponds to the center of a color pixel region, and the center of a spherical microlens ML corresponding to the edge of the pixel array does not coincide with the center of a color pixel region. The spherical microlens ML corresponding to the edge of the pixel array has an asymmetrical shape inclined in a direction in which light L is incident.

Referring to FIG. 7A, in the case of the spherical microlens ML, the position of a focus is determined by curvature and refractive index, and therefore the position of the focus varies depending on the shape of the spherical microlens ML as illustrated. However, in the case of oblique incidence at the edge of the pixel array, the focus is formed at a higher position due to field curvature aberration than in the case of normal incidence. That is, the height of the focus varies depending on the position in the pixel array. As a result, autofocus contrast (AF-C) decreases toward the edge of the pixel array where the angle of incidence of incident light increases. In addition, since incident light has different wavelengths depending on colors, chromatic aberration depending on the colors occurs when the incident light transmits through the spherical microlens. However, when the spherical microlens has the same structure, it is difficult to accurately adjust the chief ray angle depending on the wavelength of each color light. Therefore, according to the existing disclosure, there is a problem in that a channel difference depending on each color is not able to be optimized. Here, the channel difference refers to a difference between the maximum sensitivity and the minimum sensitivity of a pixel depending on color.

To solve this problem, as illustrated in FIG. 7B, the inclined asymmetric spherical microlens ML may be used such that the light L obliquely incident to the edge of the pixel array is focused on the sensor in the vertical direction. Additionally, spherical microlenses ML for respective colors may be designed to be asymmetrical in different shapes such that the focuses are formed at the same height for the respective colors. However, in the case of these spherical microlenses ML, there is a problem in that it is very difficult to form a physical shape that has an accurate function. In particular, the spherical microlenses ML may be manufactured through patterning using a photolithography process and a reflow process, but it is difficult to implement an accurate shape through the reflow process.

Referring to FIGS. 8A and 8B, the image sensor according to some example embodiments of the present disclosure includes the meta-microlenses MML instead of the spherical microlenses ML (refer to FIGS. 7A and 7B). The meta-microlens MML corresponding to the center of the pixel array may easily change the optical path by controlling the widths and densities of the nanoposts NP in the region where light L is vertically incident and the region where light L is obliquely incident. In the case of the meta-microlens MML according to some example embodiments of the present disclosure, the focuses may be controlled to be formed at the same height by simply controlling the diameters or densities of the nanoposts NP for respective colors. Moreover, the meta-microlens MML according to some example embodiments of the present disclosure is comparatively easy to implement because the diameters and pitches of the nanoposts NP are easily controlled using photolithography and etching processes.

The image sensor according to some example embodiments of the present disclosure employs the above-described structure, but the shapes of the meta-microlenses may be sequentially changed from the center of the pixel array toward the edge of the pixel array. That is, in some example embodiments of the present disclosure, the diameters or densities of the nanoposts may be increased from the center of the pixel array toward the edge of the pixel array.

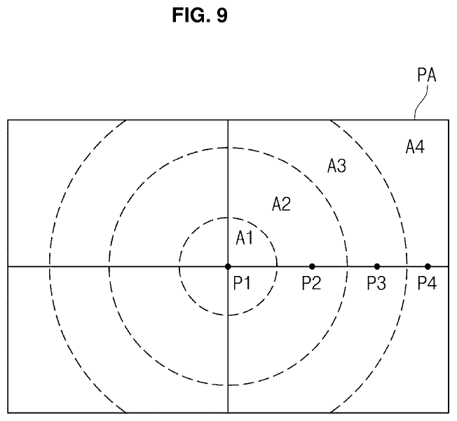

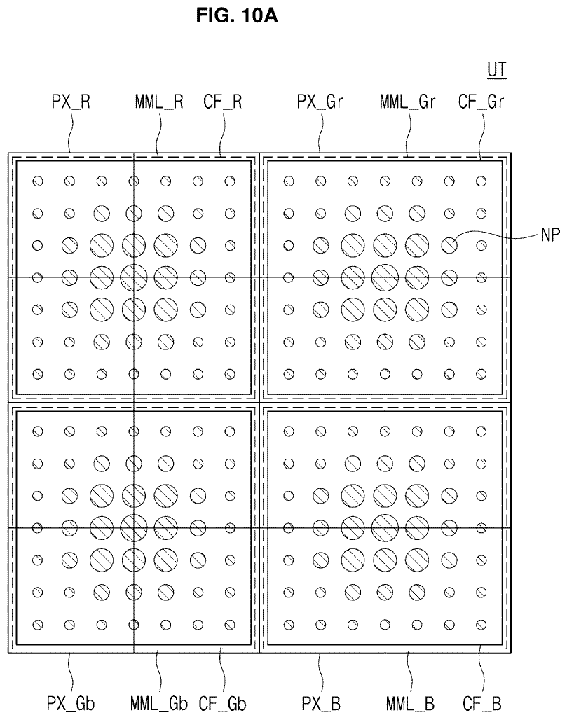

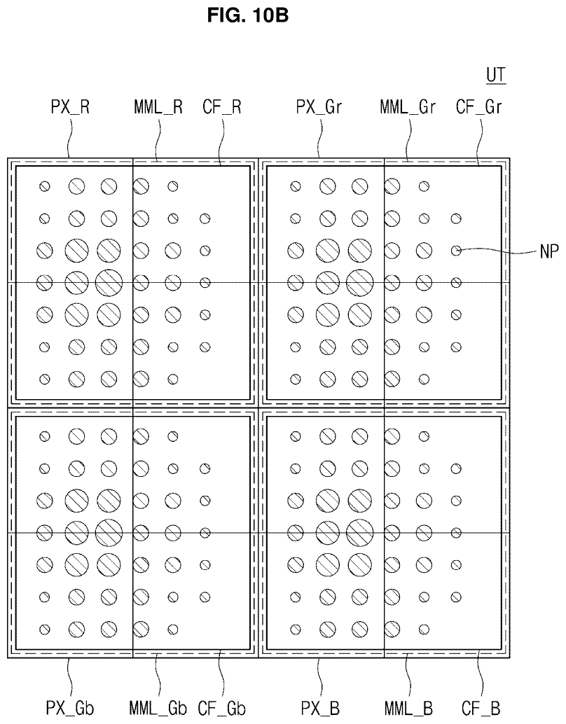

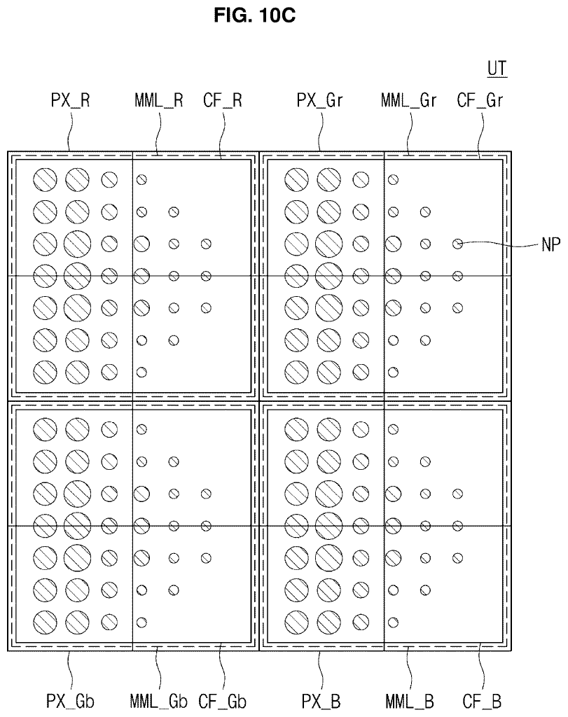

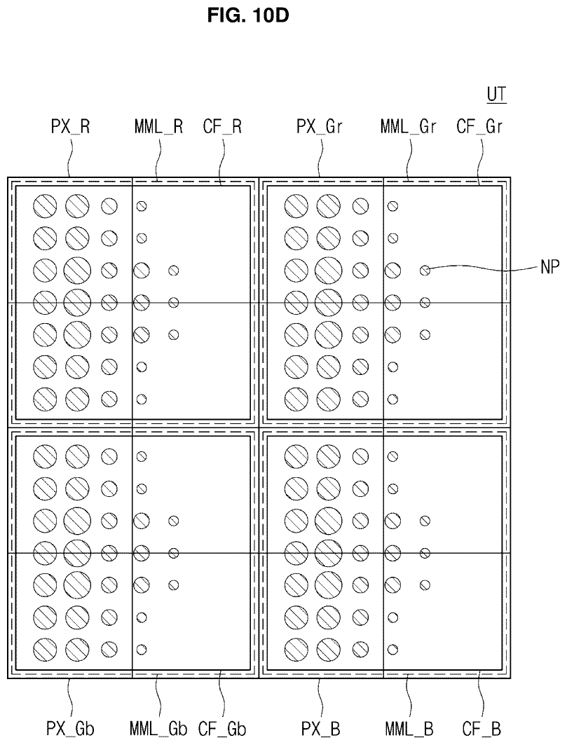

FIG. 9 is a view illustrating pixel regions in an image sensor according to some example embodiments of the present disclosure, and FIGS. 10A to 10D are plan views sequentially illustrating the shapes of meta-microlenses depending on the positions P1, P2, P3, and P4 of the pixel regions. In FIGS. 10A to 10D, the illustrated portions correspond to regions corresponding to a unit pattern in the Bayer pattern of FIG. 5A. Here, the shape or number of regions is arbitrarily selected for convenience of description, and in some example embodiments of the present disclosure, the diameters or densities of nanoposts in the respective regions may sequentially vary from the center of a pixel array toward the edge of the pixel array. Accordingly, in practice, the boundaries between the regions may not be distinguished.

Referring to FIGS. 9, 10A, and 10D, the pixel array PA may include a plurality of regions, for example, first to fourth regions A1, A2, A3, and A4 sequentially arranged in the direction from the center toward the edge. Here, the first to fourth regions A1, A2, A3, and A4 are provided as examples, and the number of regions may be set in various ways. For convenience of description, four regions are illustrated in these example embodiments. In some example embodiments of the present disclosure, the first to fourth regions A1, A2, A3, and A4 may be provided in the shape of concentric circles. In addition, in these example embodiments, unit patterns UT at only four points selected in the lengthwise direction of the pixel array PA are illustrated. However, nanoposts NP may be radially arranged toward the center of the pixel array PA. However, the shape of the regions is not limited thereto, and the regions may be provided in different shapes depending on the configuration of the optical lens assembly of FIG. 3. For example, the regions may have the shape of concentric ellipses.

In some example embodiments of the present disclosure, in meta-microlenses MML, the diameters of the nanoposts NP in refractive index peak regions may be increased from the center of the pixel array PA toward the edge of the pixel array PA, that is, from the first region A1 toward the fourth region A4. In particular, in separate color pixel regions, the diameters of the nanoposts NP corresponding to the refractive index peak regions may be increased from the first region A1 toward the fourth region A4. Alternatively, the nanoposts NP in the separate color pixel regions may have an increasing average diameter in the direction from the first region A1 toward the fourth region A4 even though not corresponding to the refractive index peak regions. Furthermore, not only the diameter but also the density of the nanoposts NP may have a larger value from the first region A1 toward the fourth region A4. In addition, the nanoposts NP may have a decreasing pitch from the first region A1 toward the fourth region A4.

As compared with when a spherical microlens is used for light collection, the image sensor having the above-described structure has improved sensitivity, especially, improved sensitivity to oblique light.

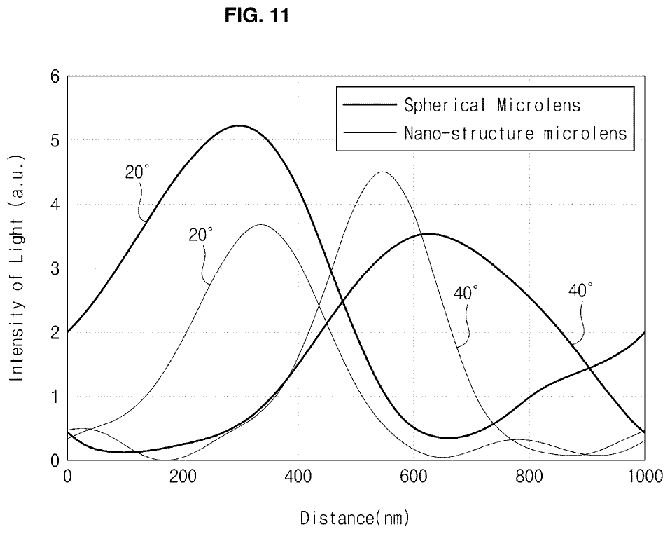

FIG. 11 is a graph depicting the amounts of light sensed by the image sensor employing the spherical microlens and the image sensor employing the meta-microlens according to some example embodiments of the present disclosure. In the following example embodiments, all components other than the spherical microlens and the meta-microlens are kept the same, and only the spherical microlens and the meta-microlens are differently employed.

In FIG. 11, based on when the incidence angle of oblique light on each image sensor is 30°, the graph on the left side shows the amount of light sensed at an angle of −10°, that is, when the angle of incidence is 20 degrees (°), and the graph on the right side shows the amount of light sensed at an angle of +10°, that is, when the angle of incidence is 40 degrees (°)

Referring to FIG. 11, in the case in which the spherical microlens is used, the peak width is very broad when the incidence angle is 20 degrees and 40 degrees. In contrast, when the meta-microlens is used, the peak width is significantly reduced than when the spherical microlens is used. In the light intensity graph, as the peak width is reduced, it is comparatively easy to distinguish between two incident lights, and as the overlapping portion is increased, it is difficult to distinguish between two incident lights. In particular, when the widths of two peaks are broad and overlap each other, it is difficult to identify the angle of incident light. However, when the meta-microlens according to some example embodiments of the present disclosure is used as illustrated, the peaks are narrowed at 20 degrees and 40 degrees, and the overlapping area itself is significantly reduced. Accordingly, it is comparatively easy to distinguish between the two incident lights, and thus the sensitivity may be increased.

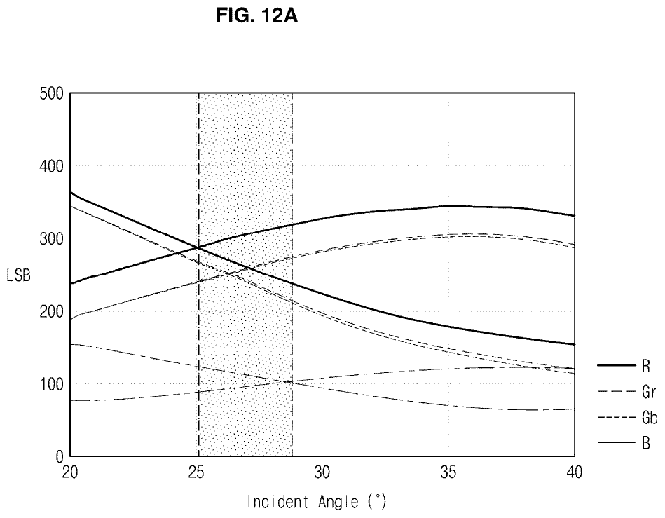

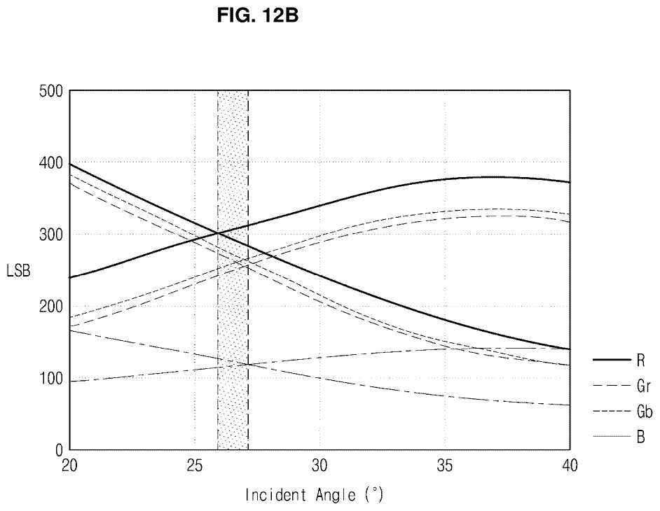

FIGS. 12A and 12B are graphs depicting angular response results in the image sensor employing the spherical microlens and the image sensor employing the meta-microlens of the present disclosure. FIGS. 12A and 12B illustrate the angular response results while the angle is changed by +10 degrees and −10 degrees based on an incidence angle of 30 degrees. Each graph is a simulation result measured using four unit pixels (that is, a red unit pixel PX_R, a green unit pixel PX_Gr, a green unit pixel PX_Gb, and a blue unit pixel PX_B) as an example. Each graph represents a different value depending on a phase difference of light sensed by two adjacent pixels. The left and right graphs that intersect each other are calculated based on phase difference data of light sensed by the two adjacent pixels.

Referring to FIGS. 12A and 12B, in the case of the image sensor employing the spherical microlens, the intersection points of the graphs for respective colors are very different depending on the angle of incidence. As illustrated, in the case of the image sensor employing the spherical microlens, the graphs of red light intersect each other at an incidence angle of about or exactly 25 degrees, and the graphs of blue light intersect each other at an incidence angle of about or exactly 28 degrees. In contrast, in the case of the image sensor employing the meta-microlens according to some example embodiments of the present disclosure, the graphs of all color lights intersect between about or exactly 26 degrees and about or exactly 27 degrees.

Due to the chromatic aberration of each color, the intersection points in the image sensor employing the spherical microlens appear differently depending on the angle of incidence. This means that light is sensed to different degrees depending on colors for the same angle of incidence. In contrast, the image sensor employing the meta-microlens according to some example embodiments of the present disclosure senses light to almost the same degree regardless of colors for the same angle of incidence. Accordingly, it can be seen that in the case of the image sensor of the present disclosure, the chromatic aberration depending on colors is significantly reduced and there is almost no channel difference.

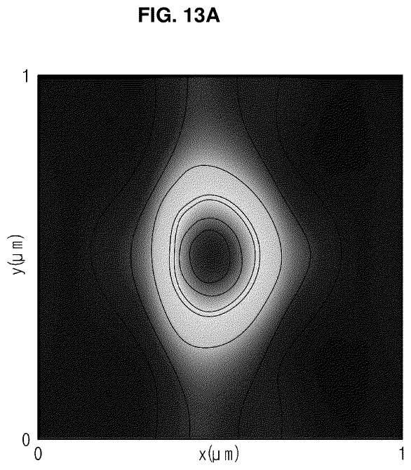

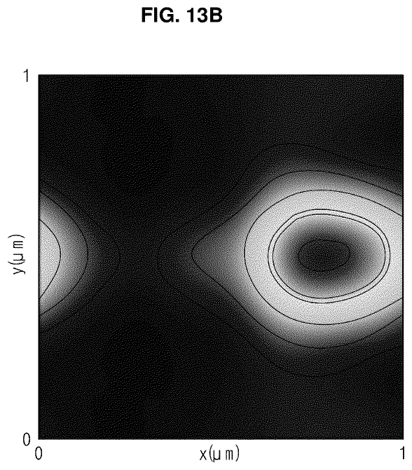

FIGS. 13A and 13B are simulation result views illustrating light condensing results in the image sensor employing the spherical microlens and the image sensor employing the meta-microlens of the present disclosure. This simulation represents simulation results for light having an azimuth angle of 0 degrees and an incidence angle of 30 degrees, and it means that the light density increases from blue toward red.

Referring to FIGS. 13A and 13B, in the case of the image sensor employing the spherical microlens, the focus is formed at the place other than the center of the unit pixel. In contrast, in the case of the image sensor employing the meta-microlens of the present disclosure, the focus is formed at the center. Accordingly, it can be seen that the light condensing effect of the image sensor employing the meta-microlens of the present disclosure is very high, which means an improvement in the sensitivity of the image sensor.

Although the image sensor according to some example embodiments of the present disclosure has very small chromatic aberration and channel difference when compared to the image sensor employing the spherical microlens, the image sensor according to some example embodiments of the present disclosure may implement additional chromatic aberration correction and reduction of channel difference by shifting the color filters.

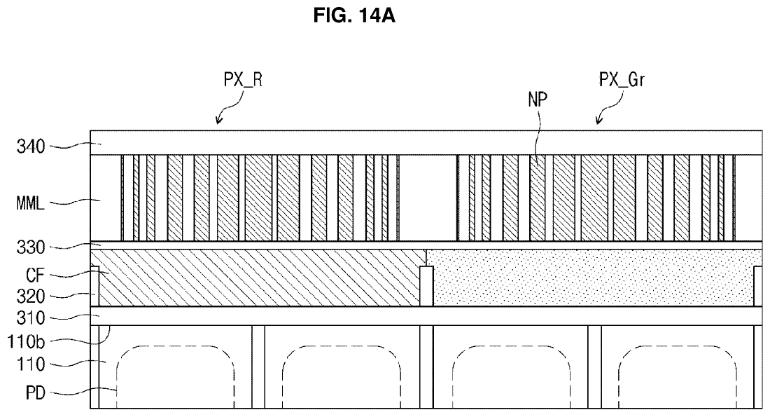

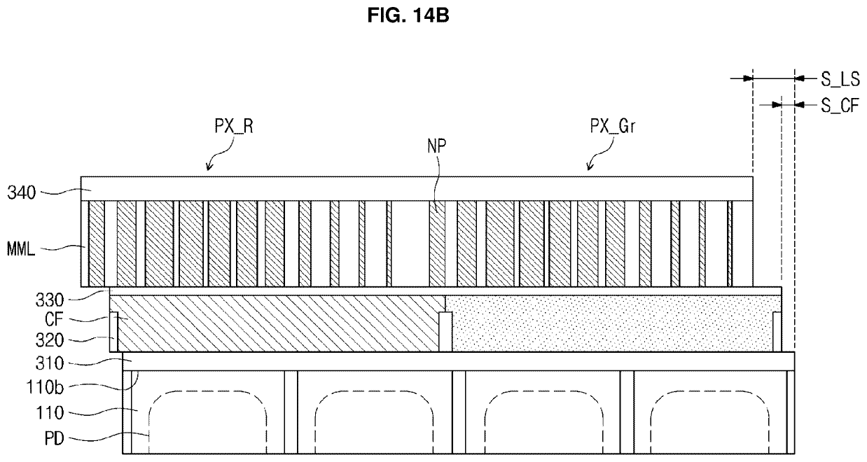

FIGS. 14A and 14B are sectional views illustrating some of the pixels at the center and edge of the image sensor according to some example embodiments of the present disclosure.

Referring to FIGS. 14A and 14B, the image sensor according to some example embodiments of the present disclosure includes the meta-microlens MML instead of a spherical microlens. A nano-spherical microlens corresponding to the center of the pixel array controls the width and density of the nanoposts NP in a region where light is perpendicularly incident and a region where light is obliquely incident and corrects additional chromatic aberration and channel difference by shifting the meta-microlens MML and the color filter CF toward the center of the pixel array.

In some example embodiments of the present disclosure, the color filter CF may be shifted by a certain distance S_CF from a corresponding unit pixel in a direction in which light is incident, that is, toward the center of the pixel array. The meta-microlens MML may also be shifted by a certain distance S_LS from the corresponding unit pixel in the direction in which the light is incident, that is, toward the center of the pixel array.

Due to the shift of the color filter CF and the meta-microlens MML, the region of the corresponding unit pixel, the region where the color filter CF is provided, and the region where the meta-microlens MML is provided may not partially overlap one another. That is, the color filter CF does not overlap the corresponding unit pixel region by the distance by which the color filter CF is shifted toward the center of the pixel array. Accordingly, the overlapping area of the region where each color filter CF is provided and the region where the corresponding unit pixel is provided may decrease from the center toward the edge.

Likewise, the meta-microlens MML does not overlap the corresponding unit pixel region by the distance by which the meta-microlens MML is shifted toward the center of the pixel array. Accordingly, the overlapping area of the region where each meta-microlens MML is provided and the region where the corresponding unit pixel is provided may decrease from the center toward the edge.

The shift distance S_SL of the meta-microlens MML may be greater than the shift distance S_CF of the color filter CF.

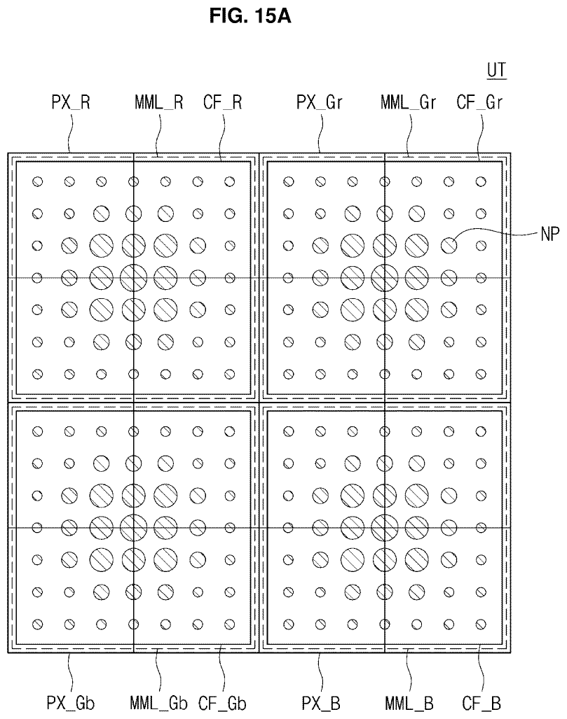

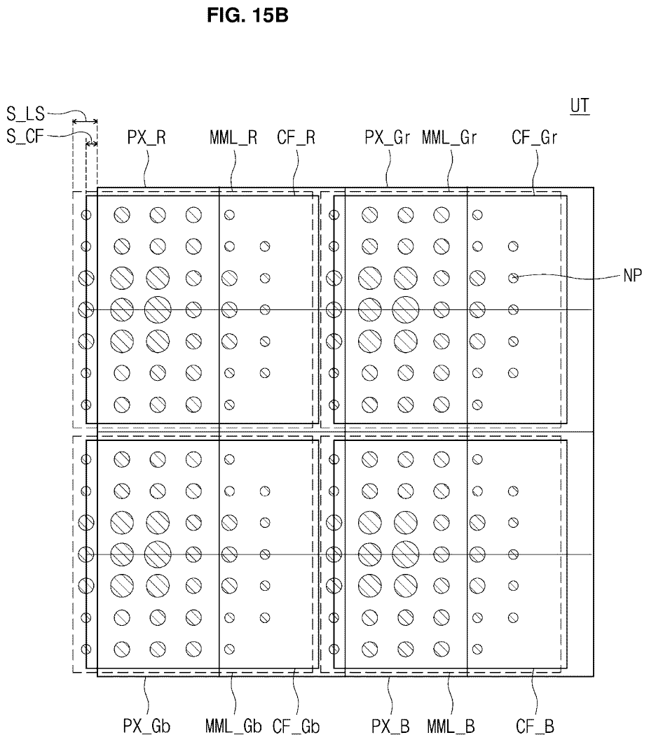

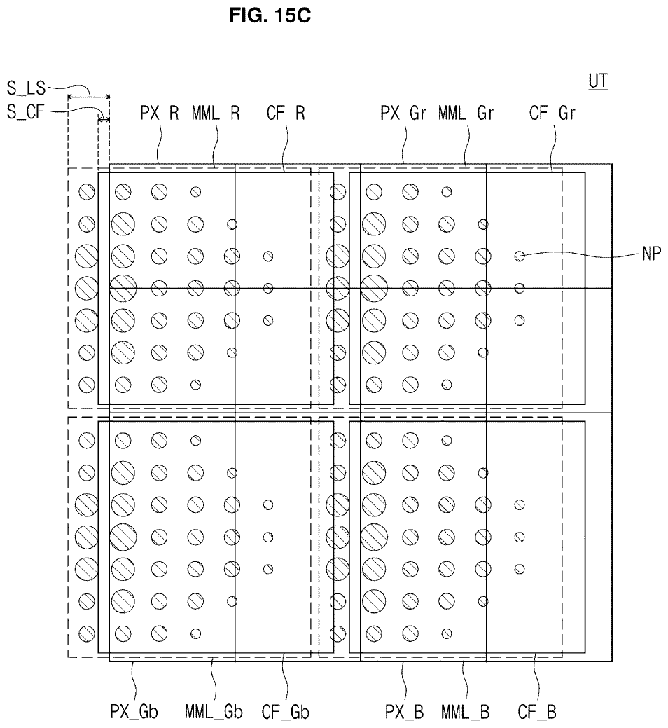

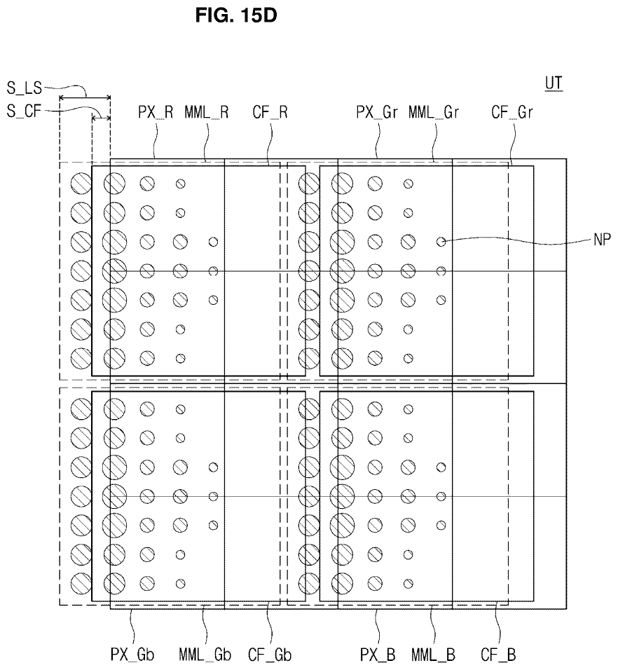

FIGS. 15A to 15D are plan views sequentially illustrating the shapes of the meta-microlenses MML depending on the positions P1, P2, P3, and P4 in the pixel array illustrated in FIG. 9.

Referring to FIGS. 9 and 15A to 15D, the shift distances of the color filters CF may be increased from the center of the pixel array PA toward the edge of the pixel array PA, that is, from the first region A1 toward the fourth region A4. At this time, the color filters CF are shifted by a certain distance toward the center of the pixel array PA, that is, toward the first region A1, and the shifted distance S_CF may be gradually increased toward the edge. In addition, the meta-microlenses MML may be shifted toward the center of the pixel array PA by a larger distance than the color filter CF, and the shift distance S_LS may also be increased toward the edge.

Due to the shift of the color filter CF and the meta-microlens MML, the non-overlapping region between the color filter CF, the meta-microlens MML, and the corresponding unit pixel may also be increased from the first region A1 toward the fourth region A4.

According to some example embodiments of the present disclosure, chromatic aberration may be more precisely corrected by differently setting the degree of shift for each color filter.

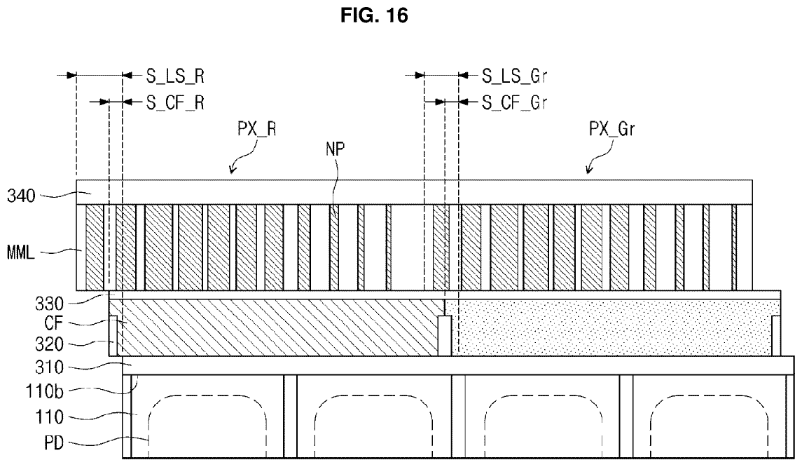

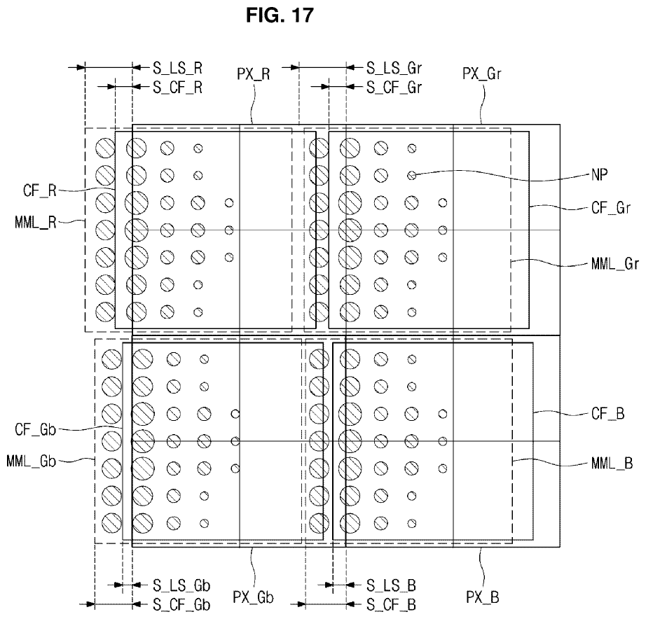

FIG. 16 is a sectional view illustrating that in the image sensor according to some example embodiments of the present disclosure, not only the meta-microlenses MML but also the color filters are shifted toward the center of the pixel array and the color filters are shifted to different degrees depending on colors. FIG. 17 is a plan view at a point corresponding to P4 in FIG. 9.

Referring to FIGS. 16 and 17, chromatic aberration occurs due to different wavelength bands for respective colors and a resulting difference in refractive index.

Accordingly, in the case of the meta-microlens MML having the same structure, chromatic aberration may occur although the chromatic aberration is less than that of a spherical microlens, and an optical path needs to be modified accordingly.

To correct the chromatic aberration, the diameter, density, and pitch of the meta-microlens MML may be changed, and as illustrated in FIGS. 16 and 17, the color filter CF may be shifted to different degrees.

For example, the color filter CF may be shifted by a certain distance from the corresponding unit pixel PX_R, PX_Gr, PX_Gb, and PX_B in a direction in which light is incident, that is, toward the center of the pixel array. However, the shift distance S_CF_R of the red color filter CF_R, the shift distances S_CF_Gr and S_CF_Gb of the green color filters CF_Gr and CF_Gb, and the shift distance S_CF_B of the blue color filter CF_B may be different from one another. According to some example embodiments of the present disclosure, the shift distance S_CF_R of the red color filter CF_R may be greater than the shift distances S_CF_Gr and S_CF_Gb of the green color filters CF_Gr and CF_Gb or the shift distance S_CF_B of the blue color filter CF_B, and the shift distances S_CF_Gr and S_CF_Gb of the green color filters CF_Gr and CF_Gb may be greater than or equal to the shift distance S_CF_B of the blue color filter CF_B. Here, the shift distances S_CF_Gr and S_CF_Gb of the green color filters CF_Gr and CF_Gb may be equal to or different from each other.

The meta-microlens MML may also be shifted by a certain distance from the corresponding unit pixel in the direction in which the light is incident, that is, toward the center of the pixel array.

For example, the meta-microlens MML may be shifted by a certain distance from the corresponding unit pixel PX_R, PX_Gr, PX_Gb, and PX_B in the direction in which the light is incident, that is, toward the center of the pixel array. However, the shift distance S_LS_R of the red meta-microlens LS_R, the shift distances S_LS_Gr and S_LS_Gb of the green meta-microlenses LS_Gr and LS_Gb, and the shift distance S_LS_B of the blue meta-microlens LS_B may be different from one another. According to some example embodiments of the present disclosure, the shift distance S_LS_R of the red meta-microlens LS_R may be greater than the shift distances S_LS_Gr and S_LS_Gb of the green meta-microlenses LS_Gr and LS_Gb or the shift distance S_LS_B of the blue meta-microlens LS_B, and the shift distances S_LS_Gr and S_LS_Gb of the green meta-microlenses LS_Gr and LS_Gb may be greater than or equal to the shift distance S_LS_B of the blue meta-microlens LS_B. Here, the shift distances S_LS_Gr and S_LS_Gb of the green meta-microlenses LS_Gr and LS_Gb may be equal to or different from each other.

The degree of shift of the color filters CF may be derived by adjusting the diameter, density, and pitch of the nanoposts NP in consideration of the difference in phase difference distribution for each wavelength. In particular, when the focal length is fixed, the phase distribution depending on the representative wavelength for each color filter may be calculated, and when the size distribution of the nanoposts NP is arranged to correspond to the corresponding phase distribution, the meta-microlens MML having the same focus for each color may be designed, unlike a spherical microlens.

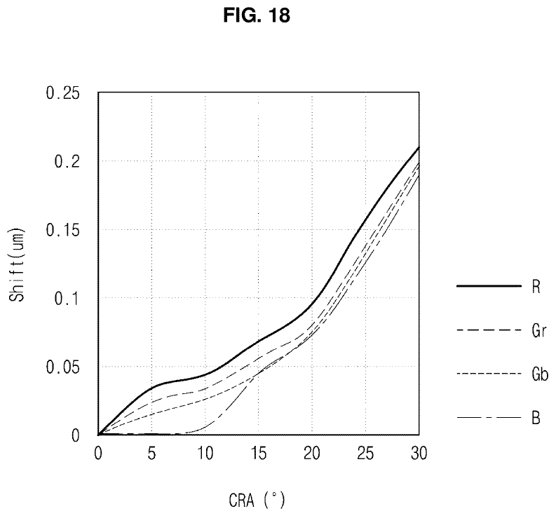

FIG. 18 is a graph depicting a shift value of each meta-microlens depending on the incidence angle of a chief ray.

Referring to FIG. 18, the meta-microlens may be shifted to different degrees depending on the angle of the chief ray. In particular, the shift value of the meta-microlens corresponding to the red color having a long wavelength may be largest, and the shift value of the meta-microlens corresponding to the blue color having a short wavelength may be smallest.

The image sensor of the present disclosure, which is implemented through the shift of the meta-microlens and the color filter, has significantly reduced chromatic aberration depending on colors and has little to no channel difference, and thus the sensitivity is improved.

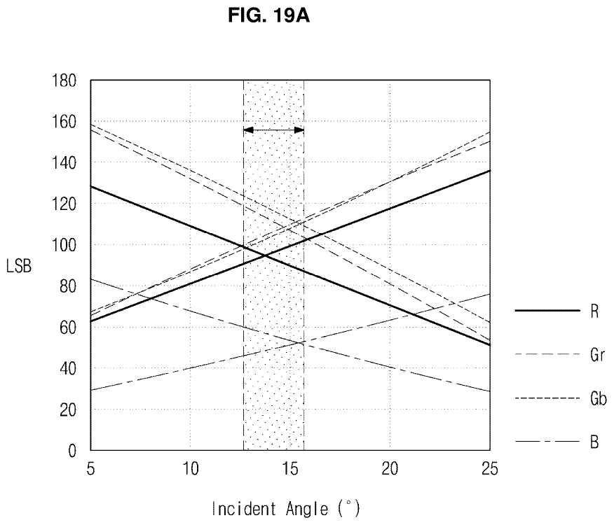

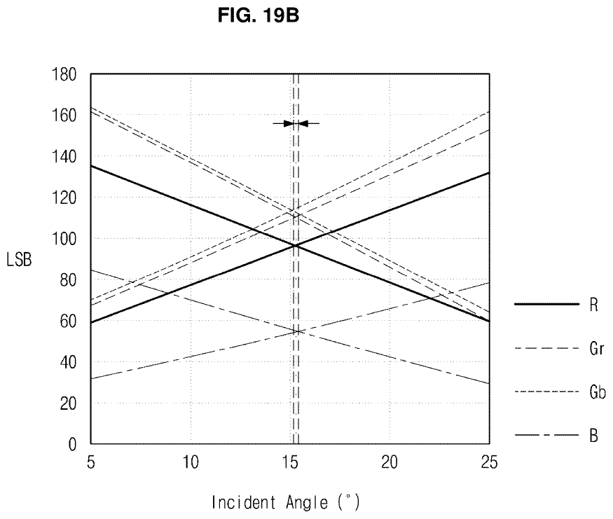

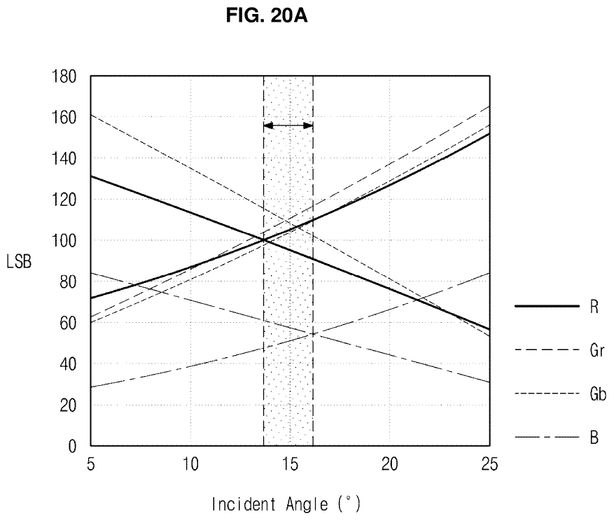

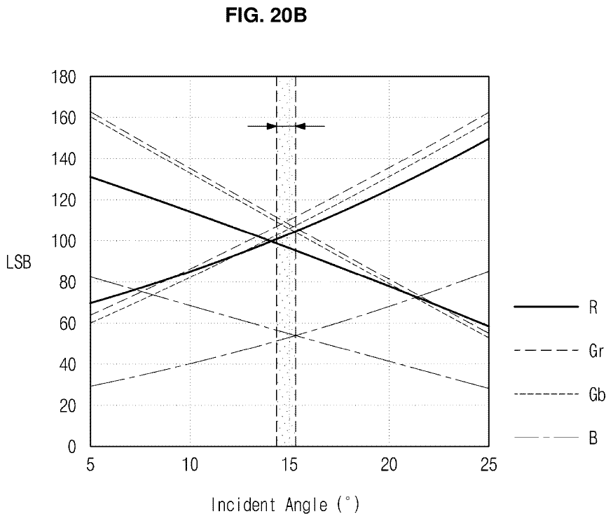

FIGS. 19A and 19B are graphs depicting angular response results in the image sensor employing the spherical microlens and the image sensor employing the meta-microlens of the present disclosure. FIGS. 19A and 19B illustrate the angular response results while the angle is changed by +10 degrees and −10 degrees based on an incidence angle of 15 degrees. FIGS. 20A and 20B are graphs depicting angular response results in the image sensor employing the spherical microlens and the image sensor employing the meta-microlens of the present disclosure. FIGS. 20A and 20B illustrate the angular response results while the angle is changed by +10 degrees and −10 degrees based on an incidence angle of 30 degrees. Each graph is a simulation result measured using four colors R, Gr, Gb, and B as examples.

Referring to FIGS. 19A, 19B, 20A, and 20B, in the case of the image sensor employing the spherical microlens, the intersection points of the graphs for the respective colors are different depending on the angle of incidence. Due to the chromatic aberration of each color, the intersection points in the image sensor employing the spherical microlens appear differently depending on the angle of incidence. This means that light is sensed to different degrees depending on colors for the same angle of incidence.

When the meta-microlens according to some example embodiments of the present disclosure is employed, AF-C and channel difference values may be significantly improved, as compared with when the spherical microlens is employed.

Table 1 below shows AF-C and channel difference values in a comparative example in which the spherical microlens is employed and some example embodiments in which the meta-microlens is employed.

TABLE 1

| | | |
|---|---|---|
| | Comparative | |
| Item | example | Embodiment |

| | | | |
|---|---|---|---|
| AF-C | R | 2.0 | 2.2 |
| | Gr | 2.4 | 2.7 |
| | Gb | 2.4 | 2.6 |
| | B | 2.1 | 2.2 |
| Channel | R | 28 | 16 |
| difference (%) | Gr | 11 | 17 |
| | Gb | 14 | 16 |
| | B | 48 | 34 |

Referring to Table 1, it can be seen that when the meta-microlens is employed, an improvement in the AF-C and a significant reduction in the channel difference are achieved and thus the quality of the image sensor is significantly improved, as compared with when the spherical microlens is employed. In particular, it can be seen that in the case of the blue color, the channel difference is decreased by about or exactly 10% or more (for example, about or exactly 10% to 14%) at the corresponding angle.

As such, according to some example embodiments of the present disclosure, by introducing different focal distances for respective colors and different degrees of shift of components for the respective colors to the image sensor, monochromatic aberration due to oblique light is corrected, and the channel differences are reduced at the same time. Accordingly, the image sensor having the above-described configuration improves auto focusing performance by correcting the phase difference of light transmitting through the microlens when auto-focusing using phase difference is implemented.

In the image sensor having the above-described structure, various modifications, such as changing the number and size of pixels and replacing color filters, may be made. For example, colors included in one unit pattern may be differently set, and the number of pixels may also be differently set. For example, in the above-described embodiments of the present disclosure, one unit pattern includes four unit pixels, and each unit pixel includes four pixels. However, the present disclosure is not limited thereto. Each unit pixel may include two pixels, nine pixels, sixteen pixels, or other numbers of pixels. In addition, the sizes of pixels may also be set in various ways depending on colors.

Some example embodiments of the present disclosure proposes a structure that optimizes phase correction depending on colors by employing the meta-microlens in the image sensor. Accordingly, the sensitivity of the image sensor may be improved.

Some example embodiments of the present disclosure provide the image sensors with improved auto focusing performance by correcting a phase depending on conditions of incident light.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

The above-described example embodiments have been described as an example for convenience of description. Without being limited thereto, the above-described example embodiments may be combined in various ways without departing from the spirit and scope of the present disclosure.

While the present disclosure has been described with reference to example embodiments thereof, it will be apparent to those of ordinary skill in the art that various changes and modifications may be made thereto without departing from the spirit and scope of the present disclosure as set forth in the following claims.

Accordingly, the scope of the present disclosure should not be determined by the above-described example embodiments and should be determined by the accompanying claims and the equivalents thereof.

What is claimed is:

1. An image sensor comprising:
a pixel array including a plurality of unit pixels having photoelectric conversion elements arranged in a matrix form on a semiconductor substrate in a first direction and a second direction crossing the first direction;
color filters corresponding to the unit pixels, the color filters having at least two different colors; and
meta-microlenses on the color filters and configured to condense light incident to the unit pixels,
each of the meta-microlenses including first and second nanostructures having different refractive indexes, and
the first nanostructure implemented with a plurality of nanoposts, and diameters of the nanoposts at an edge of the pixel array are greater than diameters of the nanoposts at a center of the pixel array.

2. The image sensor of claim 1, wherein the diameters of the nanoposts are sequentially increased from the center of the pixel array toward the edge of the pixel array.

3. The image sensor of claim 2, wherein each of the meta-microlenses includes a refractive index peak region having a highest effective refractive index of a meta-microlens of the meta-microlenses, and a distance between the refractive index peak region and a center of a unit pixel corresponding to the meta-microlens has different values at the center of the pixel array and the edge of the pixel array.

4. The image sensor of claim 3, wherein at least some of the nanoposts have different diameters in the corresponding unit pixel, and the nanoposts have the greatest diameter in the refractive index peak region.

5. The image sensor of claim 3, wherein the refractive index peak region is sequentially far away from the center of the corresponding unit pixel with an approach to the edge of the pixel array from the center of the pixel array.

6. The image sensor of claim 5, wherein the refractive index peak region coincides with the center of the corresponding unit pixel at the center of the pixel array.

7. The image sensor of claim 2, wherein the nanoposts in the corresponding unit pixel have different pitches and/or densities at the center of the pixel array and the edge of the pixel array.

8. The image sensor of claim 1, wherein the meta-microlenses are shifted in a direction toward the center with an approach to the edge of the pixel array from the center of the pixel array.

9. The image sensor of claim 8, wherein the color filters are shifted in a direction toward the center with an approach to the edge of the pixel array from the center of the pixel array.

10. The image sensor of claim 9, wherein a distance by which the meta-microlenses are shifted is greater than a distance by which the color filters are shifted.

11. The image sensor of claim 9, wherein
the color filters include two or more types of color filters having different colors, and
the color filters having the different colors are shifted by different distances with an approach to the edge of the pixel array from the center of the pixel array.

12. The image sensor of claim 11, wherein the color filters include a red color filter, a green color filter, and a blue color filter, and the red color filter is shifted more than the green color filter and the blue color filter.

13. The image sensor of claim 9, wherein a region where each of the color filters is provided at least partially overlaps a corresponding unit pixel region, and an overlapping area of the region where the color filter is provided and the corresponding unit pixel region is decreased from the center toward the edge.

14. The image sensor of claim 8, wherein a region where each of the meta-microlenses is provided at least partially overlaps a corresponding unit pixel region, and an overlapping area of the region where the meta-microlens is provided and the corresponding unit pixel region is decreased from the center toward the edge.

15. The image sensor of claim 1, wherein the pixel array includes a plurality of regions arranged in a direction from the center of the pixel array to the edge of the pixel array, and the plurality of regions have a shape of concentric circles.

16. The image sensor of claim 1, wherein the meta-microlenses have a flat upper surface.

17. The image sensor of claim 16, further comprising:
at least one of an anti-reflective layer, a nano-prism, a color splitter, a color sorter, or a polarizer provided on the meta-microlenses.

18. The image sensor of claim 1, wherein each of the unit pixels includes four pixels in a 2×2 array.

19. A camera module comprising:
an optical lens assembly configured to condense light from an object and form an optical image;
an image sensor configured to convert the optical image formed by the optical lens assembly into an electrical signal; and
an image signal processor configured to process the electrical signal output from the image sensor into an image signal,
the image sensor including
a pixel array including a plurality of unit pixels having photoelectric conversion elements arranged in a matrix form on a semiconductor substrate in a first direction and a second direction crossing the first direction;
color filters corresponding to the unit pixels, the color filters having at least two different colors; and
meta-microlenses on the color filters and configured to condense light incident to the unit pixels,
each of the meta-microlenses including first and second nanostructures having different refractive indexes, and
the first nanostructure implemented with a plurality of nanoposts, and diameters of the nanoposts at an edge of the pixel array are greater than diameters of the nanoposts at a center of the pixel array.

20. A method for manufacturing the meta-microlenses of the image sensor set forth in claim 1, the method comprising:
forming a low-refractive index material layer on the color filters;
forming a plurality of holes by etching the low-refractive index material layer;
filling the plurality of holes with a high-refractive index material; and
partially removing upper sides of the holes filled with the high-refractive index material through chemical mechanical polishing.
